(19) United States
(12) Patent Application Publication
(10) Pub. No.: US 2011/0101419 A1
(43) Pub. Date: May 5, 2011

(54) SEMICONDUCTOR DEVICE, METHOD OF MANUFACTURING SEMICONDUCTOR DEVICE AND OPTICAL APPARATUS

(75) Inventors: Masayuki Hata, Takatsuki-shi (JP); Yasumitsu Kunoh, Tottori-shi (JP)

(73) Assignee: Sanyo Electric Co., Ltd., Moriguchi-shi (JP)

(21) Appl. No.: 12/909,136

(22) Filed: Oct. 21, 2010

(30) Foreign Application Priority Data
Oct. 30, 2009 (JP) 2009-250159

(51) Int. Cl. H01L 29/04; H01L 21/20

(52) U.S. Cl. 257/190; 438/478; 257/E29.003; 257/E21.09

(57) ABSTRACT

This semiconductor device includes a substrate, an underlayer formed on a main surface of the substrate, a first semiconductor layer and a second semiconductor layer. Unstrained lattice constants of the underlayer and the second semiconductor layer in a second direction are larger than a lattice constant of the substrate in the second direction in an unstrained state. Lattice constants of the underlayer and the second semiconductor layer in the second direction in a state of being formed on the main surface are larger than the lattice constant of the substrate in the second direction.

### CROSS-REFERENCE TO RELATED APPLICATION

The priority application number JP2009-250159, Semiconductor Device and Method of Manufacturing the Same, Oct. 30, 2009, Masayuki Hata et al., upon which this patent application is based is hereby incorporated by reference.

### BACKGROUND OF THE INVENTION

1. Field of the Invention

The present invention relates to a semiconductor device, a method of manufacturing the semiconductor device and an optical apparatus, and more particularly, it relates to a semiconductor device comprising a substrate and a semiconductor layer formed on a surface of the substrate, a method of manufacturing the semiconductor device and an optical apparatus.

2. Description of the Background Art

A nitride-based semiconductor laser device comprising a substrate and a semiconductor layer formed on a surface of the substrate and a method of manufacturing the same are known in general, as disclosed in Japanese Patent Laying-Open No. 2008-91890, for example.

The aforementioned Japanese Patent Laying-Open No. 2008-91890 discloses a nitride-based semiconductor laser device and a method of manufacturing the same; this nitride-based semiconductor laser device comprises a substrate, a semiconductor layer and a semiconductor device layer. The substrate is made of a nitride semiconductor and formed with a groove-shaped recess portion in a high dislocation density region on a surface thereof. The semiconductor layer comprises a first nitride-based semiconductor layer containing Al, a second nitride-based semiconductor layer containing In and a third nitride-based semiconductor layer containing Al; these layers are stacked in this order on the surface of the substrate. The semiconductor device layer includes an active layer and is stacked on this semiconductor layer. In this nitride-based semiconductor laser device, a direction to which dislocations (defects) passed from the substrate to the first nitride-based semiconductor layer are propagated is controlled by employing a phenomenon in which the first nitride-based semiconductor layer is formed in a state where a growth thickness thereof on a side surface of the recess portion is different from that on a region (a bottom portion and an upper surface of an upper portion of the recess portion) other than the side surface in crystal growth of the semiconductor layer.

In the nitride-based semiconductor laser device disclosed in the aforementioned Japanese Patent Laying-Open No. 2008-91890, however, anisotropy of a strain in an in-plane direction (variation of strain magnitude depending on a direction) of the substrate, of the semiconductor layer (first to third nitride-based semiconductor layers) formed on the surface of the substrate or the semiconductor device layer including the upper active layer is not taken into consideration at all. Thus, the semiconductor laser device may have deteriorated due to application of a large strain to the semiconductor layer.

### SUMMARY OF THE INVENTION

A semiconductor device according to a first aspect of the present invention comprises a substrate made of a nitride-based semiconductor having a main surface parallel to a first direction and a second direction intersecting with the first direction, an underlayer made of a nitride-based semiconductor formed on the main surface, a first semiconductor layer made of a nitride-based semiconductor formed on a surface of the underlayer on an opposite side to the substrate, and a second semiconductor layer made of a nitride-based semiconductor formed on a surface of the first semiconductor layer on an opposite side to the underlayer, wherein a step portion extending along the first direction is formed on the main surface, lattice constants of the underlayer and the second semiconductor layer in the second direction in an unstrained state are larger than a lattice constant of the substrate in the second direction in an unstrained state, and lattice constants of the underlayer and the second semiconductor layer in the second direction in a state of being formed on the main surface of the substrate are larger than the lattice constant of the substrate in the second direction.

In the present invention, the “unstrained” state of each of the substrate, the underlayer and the second semiconductor layer means a state where each of the substrate, the underlayer and the second semiconductor layer exists separately without stacking each other.

In the semiconductor device according to the first aspect of the present invention, as hereinabove described, the underlayer having a lattice constant in the second direction in an unstrained state larger than the lattice constant of the substrate in the second direction in an unstrained state is formed in a state of being lattice-relaxed in the second direction so that the lattice constant of the underlayer in the second direction is larger than the lattice constant of the substrate in the second direction (a width direction of the device intersecting with the first direction) on the surface of the substrate formed with the step portion extending in the first direction. At this time, the second semiconductor layer having a lattice constant in the second direction in an unstrained state larger than the lattice constant of the substrate in the second direction in an unstrained state is so formed on the underlayer through the first semiconductor layer that the lattice constant of the second semiconductor layer in the second direction is larger than the lattice constant of the substrate in the second direction, whereby a strain of the second semiconductor layer in the second direction can be relaxed. Consequently, the lifetime of the semiconductor device can be increased.

In the aforementioned semiconductor device according to the first aspect, a lattice constant of the underlayer in the second direction in a region other than at least the step portion of the main surface is preferably larger than the lattice constant of the substrate in the second direction, and a lattice constant of the second semiconductor layer in the second direction in a region other than at least the step portion of the main surface is larger than the lattice constant of the substrate in the second direction. According to this structure, a strain of the second semiconductor layer (active layer) in the second direction on a central region of the substrate away from the step portion of the substrate in the second direction can be reliably relaxed. Thus, the increase in the lifetime of the semiconductor device can be reliably obtained.

In the aforementioned semiconductor device according to the first aspect, the underlayer is preferably formed on the substrate in a state where a strain of the underlayer in the first direction is larger than a strain of the underlayer in the second direction. According to this structure, an anisotropic strain can be applied in the in-plane direction of the substrate of a hexagonal compound semiconductor constituting the second semiconductor layer made of a nitride-based semiconductor. Thus, an effective mass of a hole in the vicinity of an upper end of a valence band in the second semiconductor layer is decreased, and hence the semiconductor device having a reduced threshold current can be formed.

In the aforementioned semiconductor device according to the first aspect, a lattice constant of the underlayer in the first direction in a state where the underlayer is formed on the main surface of the substrate is preferably substantially equal to a lattice constant of the substrate in the first direction. According to this structure, an anisotropic strain can be applied to the underlayer by employing the difference between lattice constants of the substrate in the first direction and the second direction and reliably differentiating between strains of the underlayer in the first direction and the second direction. Consequently, the semiconductor device having a reduced threshold current can be reliably formed.

In the aforementioned semiconductor device according to the first aspect, a lattice constant of the second semiconductor layer in the first direction in a state where the second semiconductor layer is formed on the surface of the first semiconductor layer is preferably substantially equal to a lattice constant of the underlayer in the first direction in a state where the underlayer is formed on the main surface. According to this structure, the second semiconductor layer can be easily so formed on the underlayer to which the anisotropic strain is applied as to take over the anisotropic strain, and hence the semiconductor device having a reduced threshold current can be easily formed.

In the aforementioned semiconductor device according to the first aspect, a lattice constant of the second semiconductor layer in the second direction in a state where the second semiconductor layer is formed on the surface of the first semiconductor layer is preferably substantially equal to the lattice constant of the underlayer in the second direction in a state where the underlayer is formed on the main surface. According to this structure, the second semiconductor layer can be easily so formed on the underlayer to which the anisotropic strain is applied as to take over the anisotropic strain, and hence the semiconductor device having a reduced threshold current can be easily formed.

In the aforementioned semiconductor device according to the first aspect, a thickness of the underlayer is preferably larger than a thickness of the first semiconductor layer. According to this structure, influence of the first semiconductor layer on the underlayer is decreased even in a state where the first semiconductor layer is formed on the underlayer, and hence the underlayer can be easily lattice-relaxed on the substrate.

In the aforementioned semiconductor device according to the first aspect, a lattice constant of the first semiconductor layer in the first direction in an unstrained state is preferably smaller than lattice constants of the underlayer in the first direction in an unstrained state, and a lattice constant of the first semiconductor layer in the second direction in an unstrained state is preferably smaller than the lattice constant of the underlayer in the second direction in an unstrained state. Even when the first semiconductor layer having a lattice constant smaller than the lattice constants of the underlayer in an unstrained state is formed on the surface of the underlayer as just described, the strain of the second semiconductor layer in the second direction can be easily relaxed by conforming the lattice constant of the underlayer in the second direction to the lattice constant of the second semiconductor layer in the second direction to form the second semiconductor layer and effectively employing the lattice relaxation of the underlayer in the second direction.

In the aforementioned semiconductor device according to the first aspect, the substrate preferably does not contain In, and the underlayer and the second semiconductor layer preferably contain In. According to this structure, the lattice constants of the underlayer and the second semiconductor layer in the second direction in an unstrained state can be easily rendered larger than the lattice constant of the substrate in the second direction in an unstrained state. When the second semiconductor layer includes an active layer, an emission wavelength can be easily increased by the contained In.

In this case, a content of In in the second semiconductor layer is preferably larger than a content of In in the underlayer. According to this structure, when the second semiconductor layer includes a light-emitting layer (active layer) or the like, an emission wavelength can be easily increased by the contained In.

In the aforementioned structure having the underlayer including In, the underlayer is preferably made of InGaN. According to this structure, the lattice constant of the underlayer in the second direction in an unstrained state can be reliably rendered larger than the lattice constant of the substrate in the second direction in an unstrained state.

In the aforementioned structure having the second semiconductor layer including In, the second semiconductor layer is preferably made of InGaN. According to this structure, the lattice constant of the second semiconductor layer in the second direction in an unstrained state can be reliably rendered larger than the lattice constant of the substrate in the second direction in an unstrained state.

In the aforementioned semiconductor device according to the first aspect, a thickness of the underlayer in a region other than the step portion is preferably smaller than a height of the step portion. According to this structure, a thickness of the underlayer in the vicinity of a corner of the step portion is smaller than a thickness of the underlayer in a region other than a bottom portion of the step portion and the step portion, and hence the underlayer is easily expanded in the second direction in the region other than the step portion. Thus, the lattice constant of the underlayer in the second direction can be easily rendered larger than the lattice constant of the substrate in the second direction in the region other than the step portion.

In the aforementioned semiconductor device according to the first aspect, the step portion preferably has a side surface extending along the first direction, and the side surface is preferably inclined in a direction in which the same makes an acute angle with the main surface of the substrate in a region other than the step portion. According to this structure, the underlayer is easily expanded in the second direction in the region other than the step portion, and hence the lattice constant of the underlayer in the second direction can be easily rendered larger than the lattice constant of the substrate in the second direction in the region other than the step portion.

In the aforementioned semiconductor device according to the first aspect, the second semiconductor layer preferably includes an active layer having a well layer, and a lattice constant of the well layer in the second direction in an unstrained state is preferably larger than the lattice constant of the substrate in the second direction in an unstrained state. According to this structure, a strain of the active layer (well layer) in the second direction constituting the second semiconductor layer formed through the first semiconductor layer can be reduced by the aforementioned underlayer. Thus, a semiconductor laser device having high luminous efficiency can be easily formed.

In this case, the second semiconductor layer is preferably a semiconductor laser device layer including the active layer, and the second semiconductor layer preferably has a waveguide extending along the first direction. According to this structure, a strain of the second semiconductor layer in the second direction can be relaxed over a substantially entire region of the semiconductor laser device in an extensional direction of a cavity. Thus, the semiconductor laser device having high luminous efficiency can be easily formed.

In the aforementioned structure in which the thickness of the underlayer in the region other than the step portion is smaller than the height of the step portion, the step portion preferably has a portion not formed with the underlayer or a portion where a thickness of the underlayer in the step portion is smaller than a thickness of the underlayer in a region other than the step portion. According to this structure, the underlayer can be completely divided between the step portion and the region other than the step portion or the thickness of the underlayer in the step portion and the thickness of the underlayer in the region other than the step portion can be reliably made different from each other, and hence the underlayer is easily expanded in the second direction in the region other than the step portion. Thus, the lattice constant of the underlayer in the second direction can be easily rendered larger than the lattice constant of the substrate in the second direction in the region other than the step portion.

A method of manufacturing a semiconductor device according to a second aspect of the present invention comprises steps of forming a step portion extending along a first direction on a main surface of a substrate made of a nitride-based semiconductor having the main surface parallel to the first direction and a second direction intersecting with the first direction, forming an underlayer made of a nitride-based semiconductor on the main surface of the substrate, forming a first semiconductor layer made of a nitride-based semiconductor on a surface of the underlayer on an opposite side to the substrate, and forming a second semiconductor layer made of a nitride-based semiconductor on a surface of the first semiconductor layer on an opposite side to the underlayer, wherein lattice constants of the underlayer and the second semiconductor layer in the second direction in an unstrained state are larger than a lattice constant of the substrate in the second direction in an unstrained state, and the step of forming the underlayer and the step of forming the second semiconductor layer include a step of forming the underlayer and the second semiconductor layer so that lattice constants of the underlayer and the second semiconductor layer in the second direction are larger than the lattice constant of the substrate in the second direction.

In the method of manufacturing a semiconductor device according to the second aspect of the present invention, as hereinabove described, the underlayer is allowed to be easily lattice-relaxed in the second direction by forming the underlayer having a lattice constant in the second direction in an unstrained state larger than the lattice constant of the substrate in the second direction in an unstrained state on the surface of the substrate formed with the step portion extending in the first direction, whereby the lattice constant of the underlayer in the second direction becomes larger than the lattice constant of the substrate in the second direction (a width direction of the device intersecting with the first direction) on the surface of the substrate. At this time, the second semiconductor layer having a lattice constant in the second direction in an unstrained state larger than the lattice constant of the substrate in the second direction in an unstrained state is so formed on the underlayer through the first semiconductor layer that the lattice constant of the second semiconductor layer in the second direction is larger than the lattice constant of the substrate in the second direction, whereby a strain of the second semiconductor layer in the second direction can be relaxed. Consequently, the lifetime of the semiconductor device can be increased.

In the aforementioned method of manufacturing a semiconductor device according to the second aspect, the step of forming the underlayer preferably includes a step of growing the underlayer at a first temperature, the step of forming the first semiconductor layer preferably includes a step of growing the first semiconductor layer at a second temperature, the step of forming the second semiconductor layer preferably includes a step of growing the second semiconductor layer at a third temperature, and the first temperature is preferably higher than the third temperature. According to this structure, the underlayer can be easily lattice-relaxed on the main surface of the substrate.

An optical apparatus according to a third aspect of the present invention comprises a semiconductor device, and an optical system adjusting emission light from the semiconductor device, wherein the semiconductor device includes a substrate made of a nitride-based semiconductor having a main surface parallel to a first direction and a second direction intersecting with the first direction, an underlayer made of a nitride-based semiconductor formed on the main surface, a first semiconductor layer made of a nitride-based semiconductor formed on a surface of the underlayer on an opposite side to the substrate, and a second semiconductor layer made of a nitride-based semiconductor formed on a surface of the first semiconductor layer on an opposite side to the underlayer, wherein a step portion extending along the first direction is formed on the main surface of the substrate, lattice constants of the underlayer and the second semiconductor layer in the second direction in an unstrained state are larger than a lattice constant of the substrate in the second direction in an unstrained state, and lattice constants of the underlayer and the second semiconductor layer in the second direction in a state of being formed on the main surface of the substrate are larger than the lattice constant of the substrate in the second direction.

In the optical apparatus according to the third aspect of the present invention, as hereinabove described, the underlayer having a lattice constant in the second direction in an unstrained state larger than the lattice constant of the substrate in the second direction in an unstrained state is formed in a state of being lattice-relaxed in the second direction so that the lattice constant of the underlayer in the second direction is larger than the lattice constant of the substrate in the second direction (a width direction of the device intersecting with the first direction) on the surface of the substrate formed with the step portion extending in the first direction. At this time, the second semiconductor layer having a lattice constant in the second direction in an unstrained state larger than the lattice constant of the substrate in the second direction in an unstrained state is so formed on the underlayer through the first semiconductor layer that the lattice constant of the second semiconductor layer in the second direction is larger than the lattice constant of the substrate in the second direction, whereby a strain of the second semiconductor layer in the second direction can be relaxed. Consequently, the optical apparatus having high reliability, capable of enduring the use for a long time by elongating the lifetime of the semiconductor device can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view for illustrating a schematic structure of a semiconductor device of the present invention;

FIG. 2 is a perspective view for illustrating the schematic structure and a manufacturing process of the semiconductor device of the present invention;

FIG. 3 is a sectional view for illustrating the schematic structure and the manufacturing process of the semiconductor device of the present invention;

FIG. 4 is a perspective view for illustrating the schematic structure and the manufacturing process of the semiconductor device of the present invention;

FIG. 5 is a front elevational view showing a structure of a nitride-based semiconductor laser device according to a first embodiment of the present invention;

FIG. 6 is a sectional view for illustrating a manufacturing process of the nitride-based semiconductor laser device according to the first embodiment of the present invention;

FIG. 7 is a sectional view for illustrating the manufacturing process of the nitride-based semiconductor laser device according to the first embodiment of the present invention;

FIG. 8 is a sectional view for illustrating the manufacturing process of the nitride-based semiconductor laser device according to the first embodiment of the present invention;

FIG. 9 is a sectional view showing a structure of a nitride-based semiconductor laser device according to a second embodiment of the present invention;

FIG. 10 is a sectional view showing a structure of a nitride-based semiconductor laser device according to a third embodiment of the present invention;

FIG. 11 is a sectional view showing a structure of a nitride-based semiconductor laser device according to a fourth embodiment of the present invention;

FIG. 12 is a sectional view for illustrating a manufacturing process of the nitride-based semiconductor laser device according to the fourth embodiment of the present invention;

FIG. 13 is a sectional view for illustrating the manufacturing process of the nitride-based semiconductor laser device according to the fourth embodiment of the present invention;

FIG. 14 is a sectional view showing a structure of a nitride-based semiconductor laser device according to a fifth embodiment of the present invention;

FIG. 15 is a sectional view showing a structure of a nitride-based semiconductor laser device according to a sixth embodiment of the present invention;

FIG. 16 is a sectional view showing a structure of a nitride-based semiconductor laser device according to a seventh embodiment of the present invention;

FIG. 17 is a schematic diagram showing a structure of an optical pickup according to an eighth embodiment of the present invention;

FIG. 18 is an external perspective view of a semiconductor laser apparatus in FIG. 17; and

FIG. 19 is a top plan view in a state where a lid of the semiconductor laser apparatus in FIG. 18 is removed.

### DESCRIPTION OF THE PREFERRED EMBODIMENTS

Embodiments of the present invention are hereinafter described with reference to the drawings.

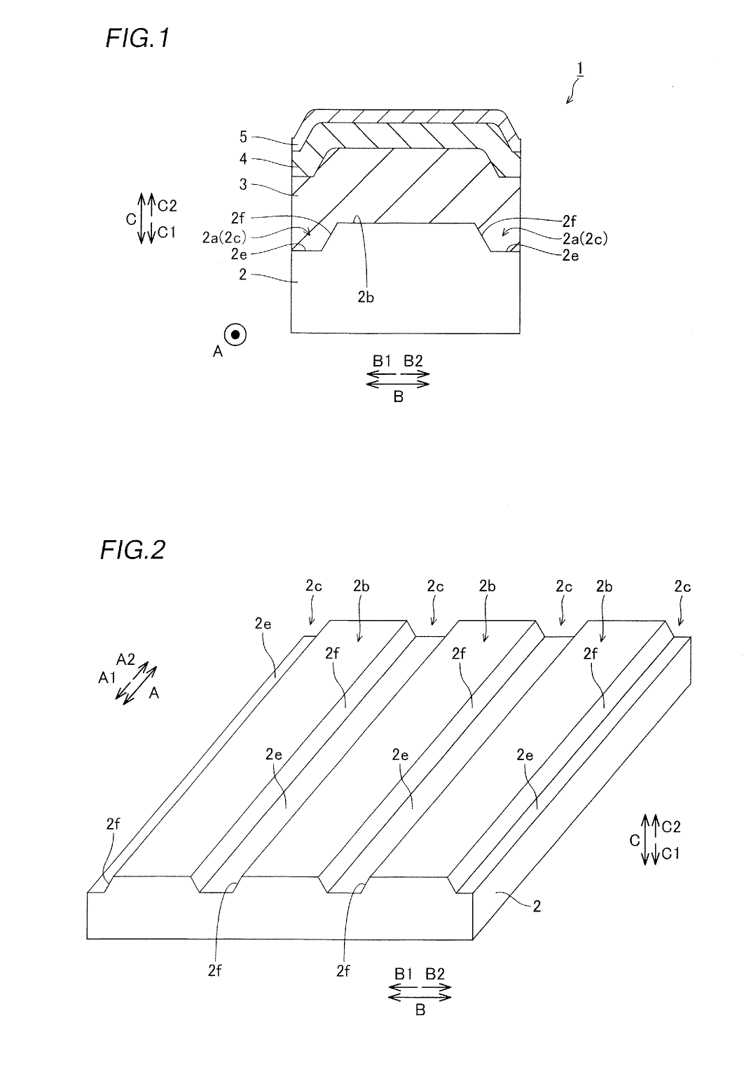

First, a structure of a semiconductor device 1 of the present invention is schematically described with reference to FIGS. 1, 2 and 4 before the embodiments of the present invention are specifically described.

The semiconductor device 1 has a structure in which an underlayer 3, a first semiconductor layer 4 and a second semiconductor layer 5 are successively stacked on a main surface of a substrate 2, as shown in FIG. 1.

Each of the substrate 2, the underlayer 3, the first semiconductor layer 4 and the second semiconductor layer 5 is made of a nitride-based semiconductor employing a group-III compound semiconductor. As shown in FIG. 1, the semiconductor device 1 includes step portions 2a extending in a first direction (along arrow A perpendicular to the plane of FIG. 1) in a striped manner on the main surface of the substrate 2. The step portions 2a each have a side surface 2f extending along the first direction, and the side surface 2f is inclined by an acute angle to the main surface of the substrate 2 in a terrace portion 2b. A portion above the terrace portion 2b, which is a region parallel to the main surface of the substrate 2 and held between the step portions 2a adjacent thereto in a second direction (width direction of the device in FIG. 1 (along arrow B)) orthogonal to arrow A, corresponds to a device forming region of the semiconductor device 1. The terrace portion 2b is an example of the “region other than the step portion” in the present invention. The aforementioned arrows A and B correspond to the “first direction” and the “second direction” in the present invention, respectively, and the same correspondence holds in the following description and embodiments.

The underlayer 3 is made of a nitride-based semiconductor employing a group-III compound semiconductor having a lattice constant β₂ along arrow B in an unstrained state larger than a lattice constant α₂ of the substrate 2 along arrow B in an unstrained state. The second semiconductor layer 5 is made of a nitride-based semiconductor of a group-III compound semiconductor having a lattice constant δ₂ along arrow B in an unstrained state larger than the lattice constant α₂ of the substrate 2 along arrow B in an unstrained state.

In a state where the underlayer 3 is formed on the surface of the substrate 2, the lattice constant β₂ of the underlayer 3 formed on the terrace portion 2b along arrow

B is larger than the lattice constant a₂ of the substrate 2 along arrow B (β₂>α₂). Similarly, in a state where the second semiconductor layer 5 is formed on the substrate 2, the lattice constant δ₂ of the second semiconductor layer 5 formed on the terrace portion 2b along arrow B is larger than the lattice constant α₂ of the substrate 2 along arrow B (δ₂>α₂).

In other words, the underlayer 3 having a lattice constant β₂ along arrow B in an unstrained state larger than the lattice constant α₂ of the substrate 2 along arrow B in an unstrained state is formed on the surface of the substrate 2 formed with the step portions 2a extending along arrow A, whereby the lattice constant β₂ of the underlayer 3 along arrow B becomes larger than the lattice constant α₂ of the substrate 2 along arrow B on the surface of the substrate 2 by employing easy occurrence of the lattice relaxation of the underlayer 3 along arrow B in the present invention. At this time, because the second semiconductor layer 5 having a lattice constant δ₂ along arrow B in an unstrained state larger than the lattice constant α₂ of the substrate 2 along arrow B in an unstrained state is so formed on the underlayer 3 through the first semiconductor layer 4 that the lattice constant δ₂ of the second semiconductor layer 5 along arrow B is larger than the lattice constant α₂ of the substrate 2 along arrow B, a strain of the second semiconductor layer 5 along arrow B is relaxed.

A non-polar plane such as a (0001) plane, a (000-1) plane, a (11-20) plane or a (1-100) plane and a semipolar plane such as a (11-22) plane, a (11-2-2) plane, a (1-101) plane or a (1-10-1) plane can be employed as plane orientation of the main surface of the substrate 2. Each of the first semiconductor layer 4 and the second semiconductor layer 5 may be constituted by a single semiconductor layer or may have a multilayer structure of a plurality of semiconductor layers. Another layer such as an insulating film or an electrode layer may be formed on an upper surface and side surfaces of the second semiconductor layer 5. Further, another layer such as an insulating film or an electrode layer may be formed on a lower surface, an upper surface and side surfaces of the substrate 2.

The substrate 2 can be preferably made of AlGaN, GaN or GaInN. When the substrate 2 is made of AlGaN, for example, the underlayer 3 may contain GaN, GaInN, AlGaN having a lower Al composition than the substrate 2, or AlInGaN having a lattice constant β₂ along arrow B in an unstrained state larger than the lattice constant α₂ of the substrate 2 along arrow B in an unstrained state. When the substrate 2 is made of GaN, the underlayer 3 may contain GaInN or AlInGaN having a lattice constant β₂ along arrow B in an unstrained state larger than the lattice constant α₂ of the substrate 2 along arrow B in an unstrained state. When the substrate 2 is made of GaInN, the underlayer 3 may contain GaInN or AlInGaN having a lattice constant β₂ along arrow B in an unstrained state larger than the lattice constant α₂ of the substrate 2 along arrow B in an unstrained state.

The first semiconductor layer 4 is made of a nitride-based semiconductor employing a group-III compound semiconductor of a different composition from the underlayer 3. For example, the first semiconductor layer 4 may include a nitride-based semiconductor made of a group-III compound semiconductor having a lattice constant γ₂ along arrow B in an unstrained state smaller than the lattice constant β₂ of the underlayer 3 along arrow B in an unstrained state. In this case, when the underlayer 3 is made of AlGaN, the first semiconductor layer 4 may contain AlGaN having a higher Al composition than the underlayer 3. When the underlayer 3 is made of GaN, the first semiconductor layer 4 may contain AlGaN. When the underlayer 3 is made of GaInN, the first semiconductor layer 4 may contain GaN, AlGaN, GaInN having a lower In composition than the underlayer 3, or AlInGaN.

The first semiconductor layer 4 can be made of a nitride-based semiconductor of a group-III compound semiconductor having a lattice constant γ₂ along arrow B in an unstrained state equal to the lattice constant β₂ of the underlayer 3 along arrow B in an unstrained state. Alternatively, the first semiconductor layer 4 can be made of a nitride-based semiconductor of a group-III compound semiconductor having a lattice constant γ₂ along arrow B in an unstrained state larger than the lattice constant β₂ of the underlayer 3 along arrow B in an unstrained state.

When the substrate 2 is made of AlGaN, the second semiconductor layer 5 may contain GaN, InGaN, AlGaN having a lower Al composition than the substrate 2, or AlInGaN having a lattice constant δ₂ along arrow B in an unstrained state larger than the lattice constant α₂ of the substrate 2 along arrow B in an unstrained state. Alternatively, when the substrate 2 is made of GaN, the second semiconductor layer 5 may contain GaInN or AlInGaN having a lattice constant δ₂ along arrow B in an unstrained state larger than the lattice constant α₂ of the substrate 2 along arrow B in an unstrained state. Alternatively, when the substrate 2 is made of GaInN, the second semiconductor layer 5 may contain GaInN having a higher In composition than the substrate 2 or AlInGaN having a lattice constant δ₂ along arrow B in an unstrained state larger than the lattice constant α₂ of the substrate 2 along arrow B in an unstrained state.

The lattice constant δ₂ of the second semiconductor layer 5 along arrow B in an unstrained state may be equal to or larger than the lattice constant β₂ of the underlayer 3 along arrow B in an unstrained state. When the underlayer 3 is made of AlₓGa_{(1-X)}N, for example, the second semiconductor layer 5 may contain Al_{Y}Ga_{(1-Y)}N (Y≦X). Alternatively, when the underlayer 3 is made of GaN, the second semiconductor layer 5 may contain GaInN. Alternatively, when the underlayer 3 is made of GaₓIn_{(1-X)}N, the second semiconductor layer 5 may contain Ga_{Y}In_{(1-Y)}N (Y≧X) or AlInGaN having a lattice constant δ₂ along arrow B in an unstrained state larger than the lattice constant α₂ of the substrate 2 along arrow B in an unstrained state. When the lattice constant γ₂ of the first semiconductor layer 4 along arrow B in an unstrained state is larger than the lattice constant β₂ of the underlayer 3 along arrow B in an unstrained state, the second semiconductor layer 5 may include a nitride-based semiconductor made of a group-III compound semiconductor such as AlBInGaTlN having a lattice constant δ₂ along arrow B in an unstrained state larger than the lattice constant γ₂ of the first semiconductor layer 4 along arrow B in an unstrained state. Thus, the substrate 2 does not contain In, and the underlayer 3 and the second semiconductor layer 5 contain In, whereby the lattice constants (β₂ and δ₂) of the underlayer 3 and the second semiconductor layer 5 along arrow B in an unstrained state can be easily rendered larger than the lattice constant α₂ of the substrate 2 along arrow B in an unstrained state in the present invention. When the second semiconductor layer 5 includes an active layer, an emission wavelength can be easily increased by an increase of the contained In.

The underlayer 3, the first semiconductor layer 4 and the second semiconductor layer 5 are preferably formed in a pseudomorphic state.

In the semiconductor device 1, the lattice constant β₂ of the underlayer 3 after forming the device along arrow B is more preferably larger than the lattice constant α₂ of the substrate 2 after forming the device along arrow B not only on the terrace portion 2b but also substantially throughout the semiconductor device 1 in the width direction.

When the substrate 2 includes the step portions 2a (groove portions 2c described later) extending in a striped manner only in one direction along arrow A, as shown in FIG. 2, the lattice constants along arrow A have a relationship in which a lattice constant α₁ of the substrate 2 after forming the device along arrow A is equal to a lattice constant β₁ of the underlayer 3 after forming the device (α₁=β₁) along arrow A. In this case, an anisotropic strain in the in-plane direction of the substrate is applied to the underlayer 3, the first semiconductor layer 4 and the second semiconductor layer 5 even in a case of an isotropic (0001) plane in the in-plane direction of the substrate. A strain of the underlayer 3 along arrow A is larger than a strain of the underlayer 3 along arrow B after forming the device. Thus, an effective mass of a hole in the vicinity of an upper end of a valence band in the second semiconductor layer 5 is decreased, and hence the semiconductor device 1 having a reduced threshold current can be formed.

As shown in FIG. 4, the substrate 2 may include step portions 2g (groove portions 2d described later) extending along arrow B in a striped manner in addition to the step portions 2a. In this case, the lattice constant β₁ of the underlayer 3 after forming the device along arrow A is larger than the lattice constant α₁ of the substrate 2 after forming the device along arrow A (β₁>α₁) throughout the semiconductor device 1 along arrow A.

A cross-sectional shape of each of the groove portions 2c for forming the step portions 2a formed in the substrate 2 may be another shape other than a shape of a groove having the side surfaces 2f inclined in a direction in which an opening width widens upward from a bottom portion 2e of the groove portion 2c shown in FIG. 2. Alternatively, the cross-sectional shape of each of the groove portions 2c may be a groove shape having side surfaces substantially perpendicular to the bottom portion 2e (bottom surface) of the groove portion 2c or may be a groove shape having both side surfaces inclined in a direction in which an opening width narrows upward from the bottom portion 2e of the groove portion 2c. The cross-sectional shape of each of the groove portions 2c may be a groove shape having stepped side surfaces. The cross-sectional shape of each of the groove portions 2c may be substantially V-shaped without the bottom portion 2e (bottom surface) or the like. The cross-sectional shape of each of the groove portions 2c may be substantially symmetrical or asymmetric.

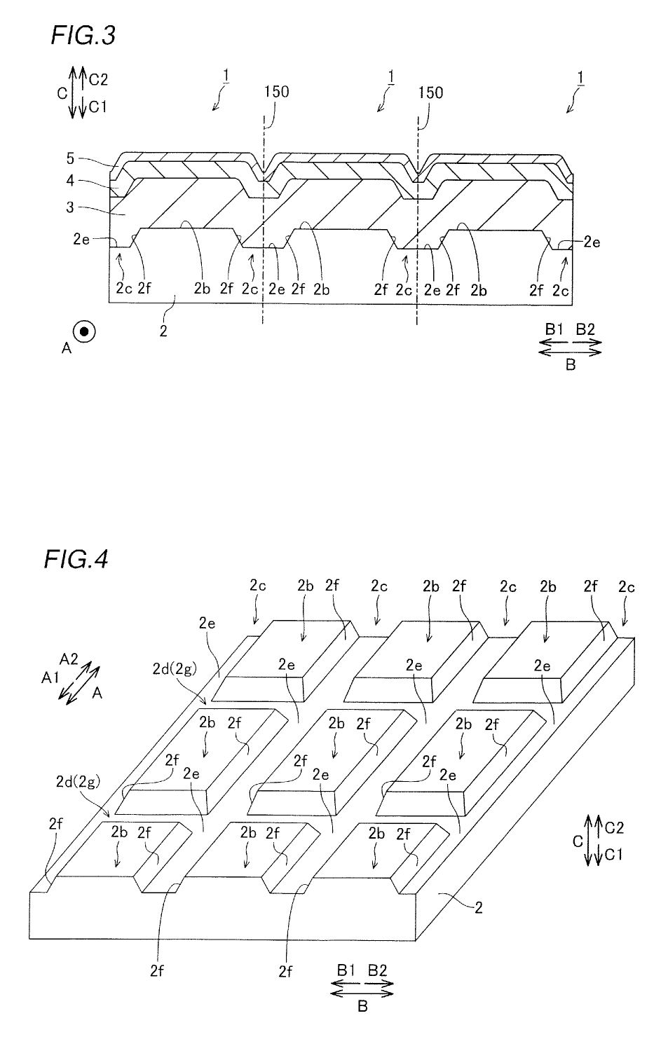

As shown in FIG. 3, the underlayer 3 may be formed on the bottom portions 2e of the groove portions 2c, but the underlayer 3 may not be formed on the bottom portions 2e of the groove portions 2c. When the underlayer 3 is not formed on the bottom portions 2e of the groove portions 2c, the underlayer 3 is divided by the groove portions 2c along arrow B, and hence the lattice constant β₂ of the underlayer 3 after formation along arrow B can be more easily rendered larger than the lattice constant α₂ of the substrate 2 along arrow B.

In the present invention, a thickness of the underlayer 3 is preferably in the range of at least about 0.5 μm and not more than about 20 μm. A height of the step portions 2a (depth of the groove portions 2c) formed in the substrate 2 is preferably in the range of at least about 0.1 μm and not more than about 30 μm. Thus, a thickness of the underlayer 3 in the vicinities of corners of the step portions 2a is smaller than a thickness of the underlayer 3 in regions (terrace portions 2b) other than the bottom portions 2e of the step portions 2a and the step portions 2a, and hence the underlayer 3 is easily expanded along arrow B in regions (terrace portions 2b etc.) other than the step portions 2a. Thus, the lattice constant β₂ of the underlayer 3 along arrow B can be easily rendered larger than the lattice constant α₂ of the substrate 2 along arrow B in the regions other than the step portions 2a.

A width (along arrow B) of the groove portions 2c is preferably larger than a thickness (along arrow C) of the first semiconductor layer 4, preferably in the range of at least about 5 μm and not more than about 400 μm.

A thickness of the underlayer 3 is more preferably formed to be larger than a thickness of the first semiconductor layer 4. Thus, because influence of the first semiconductor layer 4 on the underlayer 3 is decreased even in a state where the first semiconductor layer 4 is formed on the underlayer 3, the underlayer 3 can be easily lattice-relaxed on the substrate 2. The width of the groove portions 2c along arrow B may be wider than a width of the terrace portions 2b held between the two adjacent groove portions 2c along arrow B.

The semiconductor device 1 is applicable to light-emitting devices such as a semiconductor laser device and a light-emitting diode device, field-effect transistors, electronic devices such as a hetero bipolar transistor, photodetectors such as a photodiode and a solar cell element, photocatalyst elements and so on.

When the semiconductor device 1 is a light-emitting device, the first semiconductor layer 4 may be constituted by a first conductivity type semiconductor layer and the second semiconductor layer 5 may be formed by successively stacking the active layer and a second conductivity type semiconductor layer from the first semiconductor layer side. The active layer is constituted by a single layer, a single quantum well (SQW) structure or a multiple quantum well (MQW) structure. The active layer or a well layer may be made of a nitride-based semiconductor employing a group-III compound semiconductor having a lattice constant in an unstrained state in the in-plane direction of the substrate larger than a lattice constant of the substrate 2 in an unstrained state in the in-plane direction of the substrate. The first conductivity type semiconductor layer is constituted by a first conductivity type cladding layer having a larger band gap than the active layer and so on. There may be a carrier blocking layer having a band gap larger than the first conductivity type cladding layer between the first conductivity type cladding layer and the active layer. There may be a first conductivity type contact layer on an opposite side of the first conductivity type cladding layer to the active layer.

The second conductivity type semiconductor layer is constituted by a second conductivity type cladding layer having a larger band gap than the active layer and so on. There may be a carrier blocking layer having a band gap larger than the second conductivity type cladding layer between the second conductivity type cladding layer and the active layer. There may be a second conductivity type contact layer on an opposite side of the second conductivity type cladding layer to the active layer. A band gap of the second conductivity type contact layer is preferably smaller than that of the second conductivity type cladding layer. A first conductivity side electrode may be formed on a far side of a surface of the first conductivity type semiconductor layer from the active layer. A second conductivity side electrode is formed on the second conductivity type semiconductor layer.

When the aforementioned light-emitting device is a semiconductor laser device, there may be an optical guiding layer having a band gap between the first conductivity type cladding layer and the active layer, between the first conductivity type cladding layer and the active layer. In this case, there may be an optical guiding layer having a band gap between the second conductivity type cladding layer and the active layer, between the second conductivity type cladding layer and the active layer.

The semiconductor laser device has cavity facets consisting of cleavage planes, for example. A dielectric multilayer film of low reflectance is formed on a cavity facet on a light-emitting side of a semiconductor laser. A dielectric multilayer film of high reflectance is formed on a cavity facet opposite to the cavity facet on a light-emitting side. A multilayer film made of GaN, AlN, BN, Al₂O₃, SiO₂, ZrO₂, Ta₂O₅, Nb₂O₅, La₂O₃, SiN, AlON and MgF₂, Ti₃O₅, Nb₂O₃ or the like, or a material mixed with these can be employed for the dielectric multilayer film.

The semiconductor laser device is also applicable to a buried hetero type semiconductor laser, a gain waveguide type semiconductor laser in which a current blocking layer having an opening in a striped shape is formed on a flat upper cladding layer or a vertical cavity type semiconductor laser, in addition to a ridge waveguide type semiconductor laser having a waveguide formed in an active layer by providing a ridge constituted by a projecting portion on an upper cladding layer and arranging a dielectric current blocking layer on side surfaces of the ridge. The aforementioned semiconductor device 1 is also applicable to a light-emitting device emitting infrared light and ultraviolet light, feasible by a nitride-based semiconductor.

Next, a manufacturing process of the semiconductor device 1 of the present invention is schematically described with reference to FIGS. 1 to 4.

First, as shown in FIG. 2, the groove portions 2c extending along the first direction (along arrow A in FIGS. 1 to 3) in the in-plane direction of the substrate in a striped manner are formed on the main surface of the substrate 2. The step portions 2a arranged in both ends in the width direction (along arrow B), of the device in a state of being the semiconductor device 1 are formed by forming these groove portions 2c.

Thereafter, the underlayer 3 is grown at a first temperature, as shown in FIG. 3. At this time, the underlayer 3 is formed parallel to the main surface of the substrate 2 and in a state where the lattice constant β₂ of the underlayer 3 in the second direction (along arrow B in FIGS. 1 to 3) orthogonal to arrow A is larger than the lattice constant α₂ of the substrate 2 along arrow B (β₂>α₂). The lattice constant α₁ of the substrate 2 after forming the underlayer 3 is equal to the lattice constant β₁ of the underlayer 3 after formation along arrow A (α₁=β₁).

Next, as shown in FIG. 3, the first semiconductor layer 4 is grown on the underlayer 3 at a second temperature. The second semiconductor layer 5 is grown on the first semiconductor layer 4 at a third temperature. At this time, the second semiconductor layer 5 is formed parallel to the main surface of the substrate 2 and in a state where the lattice constant δ₂ of the second semiconductor layer 5 along arrow B orthogonal to arrow A is larger than the lattice constant α₂ of the substrate 2 along arrow B (δ₂>α₂).

As shown in FIG. 3, the underlayer 3 may be grown on the bottom portions 2e of the groove portions 2c, but the underlayer 3 may not be grown on the bottom portions 2e of the groove portions 2c. When the underlayer 3 is not grown on the bottom portions 2e of the groove portions 2c, the underlayer 3 is divided by the groove portions 2c along arrow B, and hence the lattice constant β₂ of the underlayer 3 after formation along arrow B can be more easily rendered larger than the lattice constant α₂ of the substrate 2 along arrow B. In this case, a mask for selective growth may be arranged on the bottom portions 2e of the groove portions 2c or the side surfaces 2f.

After forming the first semiconductor layer 4, the second semiconductor layer 5, etc. on the underlayer 3, the semiconductor device 1 is divided into individual chips along the groove portions 2c (isolation lines 150 in FIG. 3). In this case, the step portions 2a are left on both side ends of the semiconductor device 1 brought into a chip state (see FIG. 1) following division of the groove portions 2c. Thus, the semiconductor device 1 can be manufactured.

In the present invention, as hereinabove described, the underlayer 3 having a lattice constant β₂ along arrow B in an unstrained state larger than the lattice constant α₂ of the substrate 2 along arrow B in an unstrained state is so formed that the lattice constant β₂ of the underlayer 3 along arrow B is larger than the lattice constant α₂ of the substrate 2 along arrow B (in the width direction of the device orthogonal to the first direction (arrow A) in which the groove portions 2c extend) on the main surface of the substrate 2 (β₂>α₂). Thus, the lattice relaxation of the underlayer 3 along arrow B can easily occur. At this time, the second semiconductor layer 5 having a lattice constant δ₂ along arrow B in an unstrained state larger than the lattice constant α₂ of the substrate 2 along arrow B in an unstrained state is so formed on the underlayer 3 through the first semiconductor layer 4 that the lattice constant δ₂ of the second semiconductor layer 5 along arrow B is larger than the lattice constant α₂ of the substrate 2 along arrow B (δ₂>α₂), whereby the strain of the second semiconductor layer 5 along arrow B can be relaxed. Consequently, a lifetime of the semiconductor device 1 can be increased.

The first temperature is preferably higher than the third temperature. Thus, the lattice relaxation of the underlayer 3 in the in-plane direction of the substrate can easily occur, and hence the lattice constant β₂ of the underlayer 3 after formation along arrow B can be rendered larger than the lattice constant α₂ of the substrate 2 along arrow B (β₂>α₂). The second temperature is preferably not higher than the first temperature.

At this time, the first semiconductor layer 4 is preferably formed to have a relationship in which the lattice constant γ₁ along arrow A and the lattice constant 72 along arrow B of the first semiconductor layer 4 after formation in the in-plane direction of the substrate are equal to the lattice constant β₁ along arrow A and the lattice constant β₂ along arrow B of the underlayer 3, respectively (γ₁=β₁ and γ₂=β₂). And the second semiconductor layer 5 is preferably formed to have a relationship in which the lattice constant δ₂ along arrow A and the lattice constant δ₂ along arrow B of the second semiconductor layer 5 after formation are equal to the lattice constant β₁ along arrow A and the lattice constant β² along arrow B of the underlayer 3, respectively (δ₁=β₁ and δ₂=β₂).

As shown in FIG. 4, when the groove portions 2d extending along arrow B in a striped manner are formed in the substrate 2 in addition to the groove portions 2c, the underlayer 3 is formed on the surface of the substrate 2 in a state where the lattice constant β₁ of the underlayer 3 along arrow A is larger than the lattice constant α₁ of the substrate 2 along arrow A (β₁>α₁) throughout the underlayer 3 along arrow A. Also in this case, the first semiconductor layer 4 preferably has a relationship in which the lattice constant γ₁ along arrow A and the lattice constant γ₂ along arrow B of the first semiconductor layer 4 after formation are equal to the lattice constant β₁ along arrow A and the lattice constant β₂ along arrow B of the underlayer 3, respectively (γ₂=β₁ and γ₂=β₂). And the second semiconductor layer 5 preferably has a relationship in which the lattice constant δ₁ along arrow A and the lattice constant δ₂ along arrow B of the second semiconductor layer 5 after formation are equal to the lattice constant β₁ along arrow A and the lattice constant β² along arrow B of the underlayer 3, respectively (δ₁=β₁ and δ₂=β₂).

Embodiments of the present invention are now described.

### First Embodiment

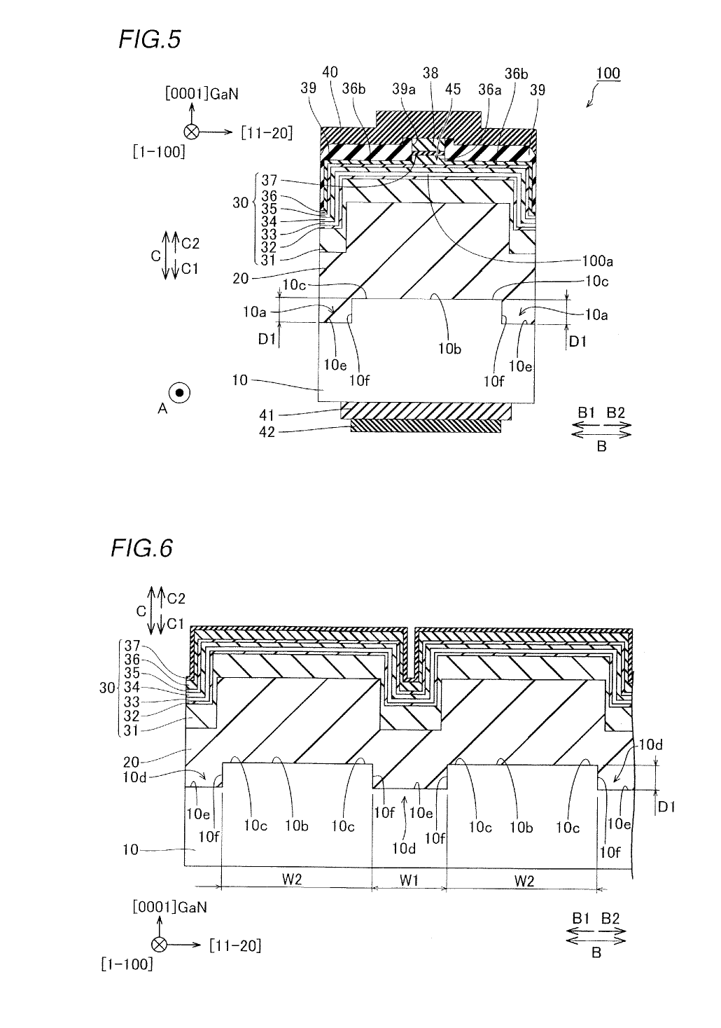

First, a structure of a nitride-based semiconductor laser device 100 according to a first embodiment of the present invention is described with reference to FIG. 5.

The nitride-based semiconductor laser device 100 is formed with a nitride-based semiconductor layer 30 through an underlayer 20 made of Ge-doped n-type In_{0.1}Ga_{0.9}N having a thickness of about 2.5 μm on a surface of an n-type GaN substrate 10 having a main surface of a (0001) plane, as shown in FIG. 5. The nitride-based semiconductor laser device 100 has a cavity length (in a direction A) of about 300 μm and a device width (along arrow B) of about 250 μm.

The n-type GaN substrate 10 is provided with respective step portions 10a on both ends thereof in a width direction of a device ([11-20] direction). Each of the step portions 10a has a step (depth) D1 of about 2 μm with respect to a terrace portion 10b arranged in a central region of the n-type GaN substrate 10 in the [11-20] direction. A lattice constant of the n-type GaN substrate 10 in the [11-20] direction (a-axis lattice constant) in an unstrained state (in a state where the n-type GaN substrate 10 exists separately without forming another semiconductor layer or the like on the n-type GaN substrate 10) is 0.3189 nm. Each of the step portions 10a is formed over an entire region along a cavity direction of the device ([1-100] direction). Therefore, the underlayer 20 having a thickness of about 2.5 μm covers an upper surface (surface on a C2 side including the step portions 10a and the terrace portion 10b) of the n-type GaN substrate 10 in a state of filling up the step portions 10a. The n-type GaN substrate 10 is an example of the “substrate” in the present invention, and the terrace portion 10b is an example of the “region other than the step portion” in the present invention.

Thus, an a-axis lattice constant of the underlayer 20 is 0.32234 nm in an unstrained state (in a state where the underlayer 20 exists separately without being formed on the n-type GaN substrate 10), whereas a lattice constant of the underlayer 20 in the [11-20] direction is 0.32028 nm in the terrace portion 10b of the n-type GaN substrate 10 when the underlayer 20 is formed on the upper surface of the n-type GaN substrate 10. In other words, the underlayer 20 has a compressive strain of 0.6% in the [11-20] direction in the terrace portion 10b. A value calculated by linear interpolation setting an a-axis lattice constant of InN to 0.3533 nm is employed for the lattice constant of the underlayer 20 in an unstrained state. The lattice constant of the underlayer 20 in the [11-20] direction is 0.32213 nm in portions above the vicinities of ends 10c of the terrace portion 10b in the [11-20] direction. In other words, the underlayer 20 has a compressive strain of 0.1% in the [11-20] direction in the portions above the vicinities of the ends 10c. The aforementioned lattice constant of the underlayer 20 in the [11-20] direction is measured by an x-ray diffraction reciprocal mapping method employing X rays narrowed down to a beam diameter of about 50 μm. In other words, the lattice constant of the underlayer 20 in the [11-20] direction is measured by x-ray diffraction reciprocal space mapping measurement in the vicinity of a (11-24) reciprocal lattice point after forming the underlayer 20.

Therefore, the underlayer 20 has a lattice constant larger than the lattice constant of the n-type GaN substrate 10 in the [11-20] direction in an unstrained state throughout the underlayer 20 in the [11-20] direction. In the vicinities of the step portions 10a, a strain of the underlayer 20 is released on side surfaces 10f of the step portions 10a, and hence a compressive strain in the portions above the vicinities of the ends 10c is smaller than a compressive strain in a portion above the vicinity of the terrace portion 10b.

A lattice constant of the underlayer 20 in the [1-100] direction after formation on the n-type GaN substrate 10 is equal to a lattice constant (=√3×0.3189 nm) of the n-type GaN substrate 10 in the [1-100] direction in an unstrained state over the entire device regardless of portions above the terrace portion 10b and the step portions 10a, and hence the underlayer 20 has a compressive strain of about 1.1% in the [1-100] direction after formation as compared with an unstrained state (lattice constant=√3×0.32234 nm). Thus, in the underlayer 20, a strain in the [1-100] direction after formation on the n-type GaN substrate 10 is larger than a strain in the [11-20] direction. The lattice constant of the underlayer 20 in the [1-100] direction is also measured by x-ray diffraction reciprocal space mapping measurement in the vicinity of a (1-104) reciprocal lattice point after forming the underlayer 20. As shown in FIG. 5, an nitride-based semiconductor layer 30 on an upper surface (surface on a C2 side) of the underlayer 20 is constituted by an n-type cladding layer 31 made of Ge-doped n-type Al_{0.03}Ga_{0.97}N, having a thickness of about 1.8 μm, an n-side carrier blocking layer 32 made of undoped Al_{0.2}Ga_{0.8}N, having a thickness of about 20 nm and an active layer 33 having an MQW structure in which four barrier layers made of undoped In_{0.15}Ga_{0.85}N, each having a thickness of about 20 nm and three quantum well layers made of undoped In_{0.3}Ga_{0.7}N, each having a thickness of about 3.5 nm are alternately stacked are formed from a lower layer toward an upper layer. The n-type cladding layer 31 is an example of the “first semiconductor layer” in the present invention, and the n-side carrier blocking layer 32, the barrier layers, the quantum well layers and the active layer 33 are an example of the “second semiconductor layer” in the present invention.

A p-side optical guide layer 34 made of undoped In_{0.01}Ga_{0.99}N, having a thickness of about 0.1 μm, a p-side carrier blocking layer 35 made of undoped Al_{0.15}Ga_{0.85}N, having a thickness of about 20 nm, a p-type cladding layer 36 made of Mg-doped p-type Al_{0.03}Ga_{0.97}N, having a thickness of about 0.45 μm and a p-side contact layer 37 made of undoped In_{0.07}Ga_{0.93}N, having a thickness of about 3 nm are formed on the active layer 33. The p-side optical guide layer 34, the p-side carrier blocking layer 35, the p-type cladding layer 36 and the p-side contact layer 37 are an example of the “second semiconductor layer” in the present invention.

The aforementioned layers 31 to 37 are formed along a surface shape of the underlayer 20.

Thus, in the n-type cladding layer 31, an a-axis lattice constant in an unstrained state is 0.31659 nm whereas a lattice constant in a portion above the terrace portion 10b is equal to the lattice constant (0.32028 nm) of the stacked underlayer 20 when forming the n-type cladding layer 31 on the underlayer 20, and the n-type cladding layer 31 has a tensile strain of 1.2% in the [11-20] direction. A value calculated by linear interpolation setting an a-axis lattice constant of AlN to 0.3112 nm is employed for the lattice constant of the n-type cladding layer 31 in an unstrained state. Further, a lattice constant of the n-type cladding layer 31 in the [11-20] direction is equal to the lattice constant (=0.32213 nm) of the stacked underlayer 20 in the portions above the vicinities of the ends 10c of the terrace portion 10b. In other words, the n-type cladding layer 31 has a tensile strain of 1.7% in the [11-20] direction in portions above the vicinities of the ends 10c.

Therefore, the n-type cladding layer 31 has a lattice constant larger than the lattice constant of the n-type

GaN substrate 10 in the [11-20] direction in an unstrained state throughout the n-type cladding layer 31 in the [11-20] direction. A tensile strain in the portion above the terrace portion 10b is smaller than a tensile strain in portions above the ends 10c.

A lattice constant of the n-type cladding layer 31 in the [1-100] direction after formation on the underlayer 20 is equal to the lattice constant of the n-type GaN substrate 10 in the [1-100] direction in an unstrained state over the entire device regardless of portions above the terrace portion 10b and the step portions 10a, and hence the n-type cladding layer 31 has a tensile strain of 0.7% in the [1-100] direction after formation as compared with an unstrained state (lattice constant=√3×0.31659 nm). Thus, a strain of the n-type cladding layer 31 in the [1-100] direction after formation on the underlayer 20 is smaller than a strain thereof in the [11-20] direction.

On the other hand, in the well layers of the active layer 33, an a-axis lattice constant in an unstrained state is 0.32922 nm whereas a lattice constant in a portion above the terrace portion 10b is equal to the lattice constant (0.32028 nm) of the underlayer 20 when forming the well layers on the underlayer 20, and the well layers of the active layer 33 have a compressive strain of 2.7% in the [11-20] direction. Further, a lattice constant of the well layers in the [11-20] direction is equal to the lattice constant (0.32213 nm) of the stacked underlayer 20 in the portions above the ends 10c of the terrace portion 10b. In other words, the well layers have a compressive strain of about 2.2% in the [11-20] direction in portions above the ends 10c.

Therefore, the well layers have a lattice constant larger than the lattice constant of the n-type GaN substrate 10 in the [11-20] direction in an unstrained state throughout the well layers in the [11-20] direction. In the vicinities of the step portions 10a, a strain of the well layers is released on the side surfaces 10f of the step portions 10a, and hence a compressive strain in the portions above the ends 10c is smaller than a compressive strain in the portion above the terrace portion 10b.

A lattice constant of the well layers in the [1-100] direction (direction A) after formation on the n-side carrier blocking layer 32 is equal to the lattice constant of the n-type GaN substrate 10 in the [1-100] direction in an unstrained state over the entire device regardless of portions above the terrace portion 10b and the step portions 10a, and hence the well layers have a compressive strain of 3.1% in the [1-100] direction after formation as compared with a lattice constant (√3×0.32922 nm) in an unstrained state. Thus, a strain of the well layers in the [1-100] direction after formation on the n-side carrier blocking layer 32 is larger than a strain thereof in the [11-20] direction.

As shown in FIG. 5, the p-type cladding layer 36 has a projecting portion 36a protruding upward (in a direction C2) from a substantially central portion of the device along arrow B, having a thickness (protrusion height) of about 0.402 μm and planar portions 36b extending on both sides of the projecting portion 36a, having a thickness of about 0.05 μm. The projecting portion 36a extends along the cavity direction in a striped manner in a state of having a width of about 1.5 μm along arrow B of the device. The projecting portion 36a of this p-type cladding layer 36 and the p-side contact layer 37 on the projecting portion 36a form a ridge 45 for constituting a waveguide in a portion of the active layer 33.

A p-side ohmic electrode 38 including a Pt layer having a thickness of about 1 nm, a Pd layer having a thickness of about 10 nm and a Pt layer having a thickness of about 30 nm from a lower layer toward an upper layer is formed on the p-side contact layer 37 constituting the ridge 45. A current blocking layer 39 made of SiO₂, having a thickness of about 200 nm is so formed as to cover upper surfaces of the planar portions 36b other than the projecting portion 36a of the p-type cladding layer 36 of the nitride-based semiconductor layer 30 and both side surfaces of the ridge 45. A p-side pad electrode 40 including a Ti layer having a thickness of about 30 nm, a Pd layer having a thickness of about 150 nm and an Au layer having a thickness of about 3 μm from a lower layer toward an upper layer is formed on upper surfaces of the p-side ohmic electrode 38 and the current blocking layer 39.

As shown in FIG. 5, an n-side ohmic electrode 41 including an Al layer having a thickness of about 6 nm, a Ti layer having a thickness of about 10 nm and a Pd layer having a thickness of about 10 nm and an n-side pad electrode 42 including an Au layer having a thickness of about 300 nm are successively formed from the side closer to a back surface of the n-type GaN substrate 10 on the back surface.

A pair of cavity facets 100a (a light-emitting surface and a light-reflecting surface) are formed on both ends of the nitride-based semiconductor laser device 100 in an extensional direction ([1-100] direction) of a cavity. The ridge 45 extends to positions formed with the cavity facets 100a along the [1-100] direction. The step portions 10a extend to the positions formed with the cavity facets 100a serving as end side surfaces of the ridge 45 along the [1-100] direction. A dielectric multilayer film (not shown) having a function of reflectance control, made of AlN, Al₂O₃ and the like is formed on the pair of cavity facets 100a by facet coating treatment in a manufacturing process.

Next, a manufacturing process of the nitride-based semiconductor laser device 100 according to the first embodiment is described with reference to FIGS. 5 to 8.

First, the n-type GaN substrate 10 having a main surface of a (0001) plane is prepared. A mask layer (not shown) in a striped shape including an Ni layer having a thickness of about 0.4 μm is formed on a prescribed region of a surface of the n-type GaN substrate 10 by electron beam evaporation or the like, and thereafter this mask layer (not shown) is employed as an etching mask for etching the n-type GaN substrate 10 up to a depth of about 2 μm (in a direction C1) from the upper surface (surface on a C2 side in FIG. 6) thereof by reactive ion etching (RIE) with Cl₂ gas. This etching is performed at an etching selectivity ratio (mask layer/n-type GaN substrate 10) of 1:10 under conditions of an etching pressure of about 3.325 kPa, plasma power of about 200 W and an etching rate of about 140 to about 150 nm/s. Thus, a plurality of groove portions 10d in a striped shape, each having a width (width of upper opening) W1 (see FIG. 6) of about 50 μm and a depth D1 (see FIG. 6) of about 2 μm, extending in the [1-100] direction are formed on the n-type GaN substrate 10. Under the aforementioned etching conditions, the right and left side surfaces 10f of the groove portions 10d are formed substantially perpendicular to the upper surface (surface on a C2 side) of the n-type GaN substrate 10. Thus, in the n-type GaN substrate 10, the terrace portions 10b held between the groove portions 10d, each having a width W2 (see FIG. 6) of about 200 μm in the [11-20] direction correspond to light-emitting portions of the nitride-based semiconductor layer 30 described later. Thereafter, the mask layer is removed.

Next, as shown in FIG. 6, the layers 31 to 37 made of nitride-based semiconductors constituting the nitride-based semiconductor layer 30 are successively formed on upper surfaces of the terrace portions 10b of the n-type GaN substrate 10 and bottom portions 10e and the side surfaces 10f of the groove portions 10d through the underlayer 20 by metal organic chemical vapor deposition (MOCVD).

More specifically, the n-type GaN substrate 10 formed with the groove portions 10d is inserted into a reactor of a hydrogen-nitrogen atmosphere. Thereafter, NH₃ gas employed as the nitrogen source for the nitride-based semiconductor layers (31 to 37) is supplied into the reactor, and the n-type GaN substrate 10 is heated up to a temperature of about 850° C. When the n-type GaN substrate 10 reaches a temperature of about 850° C., triethylgallium (TEGa) gas and trimethylindium (TMIn) gas, and monogerman (GeH₄) gas are supplied into the reactor with H₂ gas employed as carrier gas, thereby growing the underlayer 20 on the upper surface of the n-type GaN substrate 10 at a growth rate of about 0.3 μm/h.

At this time, a lattice constant of the underlayer 20 in the [11-20] direction is 0.32028 nm in a state of being formed on the terrace portions 10b (the central portions of the devices in the [11-20] direction), and hence the underlayer 20 has a compressive strain of 0.6% in the [11-20] direction. Further, a lattice constant of the underlayer 20 in the [11-20] direction is 0.32213 nm in a state of being formed on the ends 10c of the terrace portions 10b in the vicinities of the groove portions 10d, and hence the underlayer 20 has a compressive strain of 0.1% in the [11-20] direction.

On the other hand, in a state of being formed on the n-type GaN substrate 10, the lattice constant of the underlayer 20 in the [1-100] direction is equal to the lattice constant of the n-type GaN substrate 10 in the [1-100] direction in an unstrained state over the entire substrate, and hence the underlayer 20 has a compressive strain of 1.1% in the [1-100] direction.

Thereafter, in a state where the temperature of the n-type GaN substrate 10 is about 950° C., trimethylgallium (TMGa) gas and trimethylaluminum (TMAl) gas, and GeH₄ gas employed as a Ge source serving as an n-type impurity are supplied into the reactor with H₂ gas employed as carrier gas, thereby growing the n-type cladding layer 31 on a surface of the underlayer 20 at a growth rate of about 1.1 μm/h.

Then, the temperature of the n-type GaN substrate 10 is reduced to about 800° C. TEGa gas and TMIn gas are supplied into the reactor with N₂ gas employed as carrier gas, thereby growing the n-side carrier blocking layer 32 on the n-type cladding layer 31 at a growth rate of about 1.2 μm/h. Then, the four barrier layers of undoped In_{0.15}Ga_{0.85}N each having a thickness of about 20 nm and the three quantum well layers of undoped In_{0.3}Ga_{0.7}N each having a thickness of about 3.5 nm are alternately grown on a surface of the n-side carrier blocking layer 32 at a growth rate of about 0.25 μm/h. Thus, the active layer 33 having an MQW structure obtained by alternately stacking the four barrier layers and the three quantum well layers is formed.

Then, the p-side optical guide layer 34 is grown on the active layer 33. Thereafter, TMGa gas and TMAl gas are supplied into the reactor with N₂ gas employed as carrier gas, thereby growing the p-side carrier blocking layer 35 on the p-side optical guide layer 34 at a growth rate of about 1.2 μm/h.

Then, the temperature of the n-type GaN substrate 10 is increased from about 850° C. to about 1000° C. Then, TMGa gas and TMAl gas, and biscyclopentadienyl magnesium (Mg(C₅H₅)₂) gas serving as a p-type impurity are supplied into the reactor with N₂ gas employed as carrier gas, thereby growing the p-type cladding layer 36 on the p-side carrier blocking layer 35 at a growth rate of about 1.1 μm/h. Thereafter the temperature of the n-type GaN substrate 10 is reduced from about 1000° C. to about 850° C. Then, TEGa gas and TMIn gas are supplied into the reactor with N₂ gas employed as carrier gas, thereby growing the p-side contact layer 37 on the p-type cladding layer 36 at a growth rate of about 0.25 μm/h. Thus, the nitride-based semiconductor layer 30 constituted by the layers 31 to 37 made of nitride-based semiconductors is formed on the upper surfaces of the terrace portions 10b of the n-type GaN substrate 10 and the bottom and side surfaces of the groove portions 10d through the underlayer 20.

At this time, a lattice constant of the nitride-based semiconductor layer 30 in the in-plane direction of the substrate is equal to the lattice constant of the underlayer 20. In other words, the well layers in the active layer 33 have a compressive strain of about 2.7% in the [11-20] direction in the portions above the terrace portions 10b (the central portions of the devices in the [11-20] direction) and a compressive strain of about 2.2% in the [11-20] direction in the portions above the ends 10c of the terrace portions 10b.

Further, the lattice constant of the well layers in the active layer 33 in the [1-100] direction is equal to the lattice constant of the n-type GaN substrate 10 in the [1-100] direction in an unstrained state over the entire substrate, and hence the well layers have a compressive strain of 3.1% in the [1-100] direction as compared with an unstrained state.

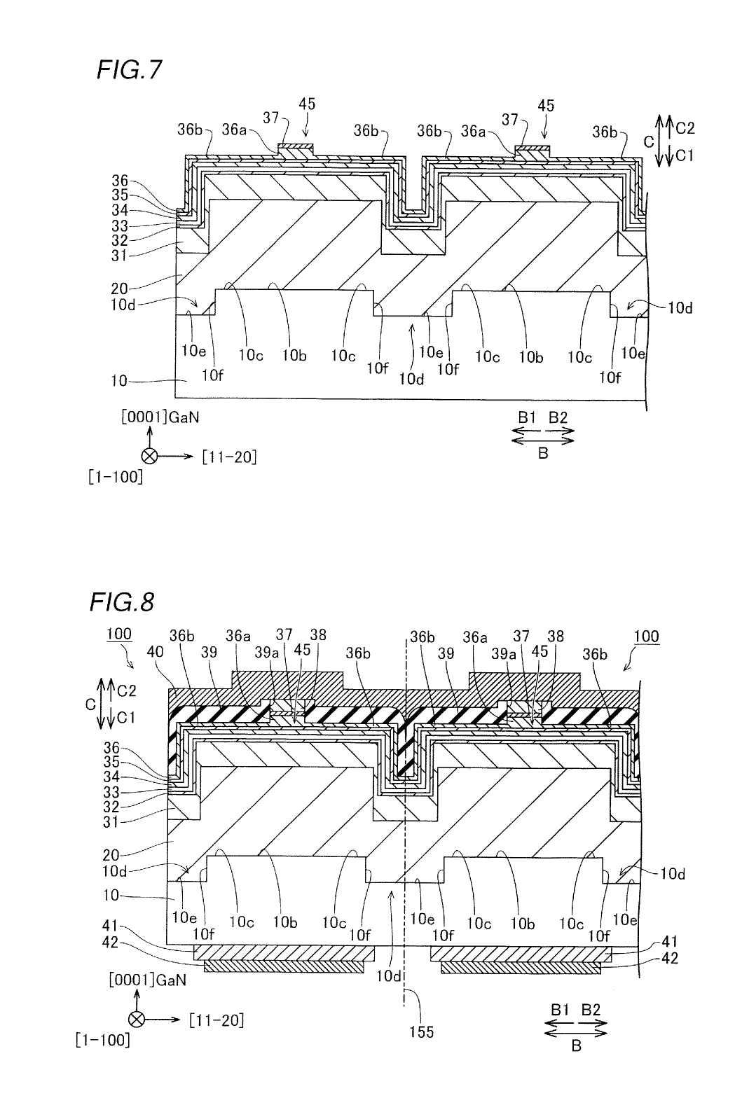

Thereafter, the ridge 45 constituted by the p-type cladding layer 36 and the p-side contact layer 37 is formed by photolithography and dry etching, as shown in FIG. 7. At this time, the ridge 45 is formed to extend in the cavity direction ([1-100] direction) in a striped manner in a state of having a width of about 1.5 μm in the width direction.

Then, an SiO₂ film having a thickness of about 0.2 μm is formed on an overall surface of the nitride-based semiconductor layer 30 by plasma CVD, and thereafter regions of the SiO₂ film corresponding to the ridges 45 are removed, thereby forming the current blocking layer 39 (see FIG. 8) having openings 39a in the regions corresponding to the ridges 45.

Then, the p-side ohmic electrode 38 is formed on a surface of the p-side contact layer 37 by electron beam evaporation, as shown in FIG. 8, and thereafter the p-side pad electrode 40 is formed on a surface of the current blocking layer 39 to be in contact with an upper surface of the p-side ohmic electrode 38 by electron beam evaporation.

Then, the back surface of the n-type GaN substrate 10 is polished up to a thickness facilitating cleavage in a cleaving step described later. Thereafter, the n-side ohmic electrodes 41 and the n-side pad electrodes 42 are successively formed on the back surface of the n-type GaN substrate 10 by electron beam evaporation.

Then, a wafer is separated into chips by cleavage along the [11-20] direction. Thereafter, the dielectric multilayer film is formed on the pair of cavity facets 100a (see FIG. 5) formed by cleavage. Finally, the wafer is separated into the individual devices in the [1-100] direction along the center (isolation line 155 in FIG. 8) of the groove portion 10d of the n-type GaN substrate 10. Thus, the step portions 10a after separating the groove portion 10d into two are left on both side ends of each chip in a width direction. Thus, the nitride-based semiconductor laser device 100 shown in FIG. 5 is formed.

As hereinabove described, the underlayer 20 having a lattice constant in the [11-20] direction (along arrow B) in an unstrained state larger than the lattice constant of the n-type GaN substrate 10 in the [11-20] direction in an unstrained state is formed on the surface of the n-type GaN substrate 10 formed with the step portions 10a extending in the [1-100] direction, whereby the lattice constant of the underlayer 20 in the [11-20] direction becomes larger than the lattice constant of the n-type GaN substrate 10 in the [11-20] direction on the surface of the n-type GaN substrate 10 by employing easy occurrence of the lattice relaxation of the underlayer 20 in the [11-20] direction. At this time, the active layer 33 including the well layers having a lattice constant in the [11-20] direction in an unstrained state larger than the lattice constant of the n-type GaN substrate 10 in the [11-20] direction in an unstrained state has a lattice constant in the [11-20] direction larger than the lattice constant of the n-type GaN substrate 10 in the [11-20] direction, whereby a strain of the active layer 33 in the [11-20] direction can be relaxed. Consequently, a lifetime of the nitride-based semiconductor laser device 100 can be increased.

The lattice constant of each of the underlayer 20 and the active layer 33 in the [11-20] direction in at least the terrace portion 10b of the main surface of the n-type GaN substrate 10 is larger than the lattice constant of the n-type GaN substrate 10 in the [11-20] direction. Thus, a strain of the active layer 33 in the [11-20] direction on the central region (terrace portion 10b) of the n-type GaN substrate 10 away from the step portions 10a in the [11-20] direction can be reliably relaxed. Thus, an increase of the nitride-based semiconductor laser device 100 in a lifetime can be reliably obtained.

The underlayer 20 is formed on the main surface of a c-plane ((0001) plane) of the n-type GaN substrate 10 in a state where a strain thereof in the [1-100] direction is larger than a strain thereof in the [11-20] direction.

Thus, an anisotropic strain can be applied in the in-plane direction of the substrate of a hexagonal compound semiconductor constituting the active layer 33 made of a nitride-based semiconductor. Thus, an effective mass of a hole in the vicinity of an upper end of a valence band in the active layer 33 is decreased, and hence the nitride-based semiconductor laser device 100 having a reduced threshold current can be formed.

The lattice constant of the underlayer 20 in the [1-100] direction in a state of being formed on the main surface of the n-type GaN substrate 10 is substantially equal to the lattice constant of the n-type GaN substrate 10 in the [1-100] direction. Thus, an anisotropic strain can be applied to the underlayer 20 by employing the difference between the lattice constants of the n-type GaN substrate 10 in the [1-100] direction and the [11-20] direction and reliably differentiating between the strains of the underlayer 20 in the [1-100] direction and the [11-20] direction. Consequently, the nitride-based semiconductor laser device 100 having a reduced threshold current can be reliably formed.

The lattice constants of the active layer 33 in the [1-100] direction and the [11-20] direction in a state of being formed on a surface of the n-type cladding layer 31 are substantially equal to the lattice constants of the underlayer 20 in the [1-100] direction and the [11-20] direction in a state of being formed on the main surface of the n-type GaN substrate 10, respectively. Thus, the well layers can be so formed on the underlayer 20 to which the anisotropic strain is applied as to take over the anisotropic strain, and hence the nitride-based semiconductor laser device 100 having a reduced threshold current can be easily formed.

A thickness of the underlayer 20 is larger than a thickness of the n-type cladding layer 31. Thus, influence of the n-type cladding layer 31 on the underlayer 20 is decreased even in a state where the n-type cladding layer 31 is formed on the underlayer 20, and hence the underlayer 20 can be easily lattice-relaxed on the n-type GaN substrate 10.

A thickness of the underlayer 20 is larger than a thickness of the n-type cladding layer 31 in a region of the terrace portion 10b. Thus, the underlayer 20 can be easily lattice-relaxed in the central region (terrace portion 10b) of the n-type GaN substrate 10 away from the step portions 10a in the [11-20] direction, and hence the strain of the active layer 33 in the [11-20] direction formed on the n-type cladding layer 31 can be reliably relaxed in the terrace portion 10b.

Lattice constants of the n-type cladding layer 31 in the [1-100] direction and the [11-20] direction in an unstrained state are smaller than lattice constants of the underlayer 20 in the [1-100] direction and the [11-20] direction in an unstrained state, respectively. Even when the n-type cladding layer 31 having a lattice constant smaller than the lattice constant of the underlayer 20 in an unstrained state is formed on the surface of the underlayer 20 as just described, the strain of the active layer 33 in the [11-20] direction formed on the n-type cladding layer 31 can be easily relaxed by effectively employing the lattice relaxation of the underlayer 20 in the [11-20] direction.

The n-type GaN substrate 10 does not contain In, and the underlayer 20 and the active layer 33 contain In. Thus, the lattice constants of the underlayer 20 and the active layer 33 in the [11-20] direction in an unstrained state can be easily rendered larger than the lattice constant of the n-type GaN substrate 10 in the [11-20] direction in an unstrained state. Further, the active layer 33 includes the well layers, and hence an emission wavelength can be easily increased by the contained In.

A content of In in the active layer 33 is larger than a content of In in the underlayer 20, and hence an emission wavelength can be easily increased by In contained in the active layer 33.

The step portions 10a are formed on the both side ends of the n-type GaN substrate 10 in the [11-20] direction. Thus, a width of the terrace portion 10b held between a pair of the step portions 10a in the [11-20] direction is decreased, and hence the underlayer 20 can be efficiently expanded in the [11-20] direction to be lattice-relaxed.

The second semiconductor layer includes the active layer 33 having the well layers, and the lattice constant of the well layers in the [11-20] direction in an unstrained state is larger than the lattice constant of the n-type GaN substrate 10 in the [11-20] direction in an unstrained state. Thus, a strain of the well layers in the [11-20] direction included in the active layer 33 formed through the n-type cladding layer 31 can be reduced by the underlayer 20. Thus, the nitride-based semiconductor laser device 100 having high luminous efficiency can be easily formed.

The ridge 45 (waveguide) extending along the [1-100] direction is formed on the p-type cladding layer 36 in the terrace portion 10b, and the step portions 10a extend to the positions formed with the cavity facets 100a serving as the end side surfaces of the ridge 45 along the [1-100] direction. Thus, the strain of the active layer 33 in the [11-20] direction can be relaxed over the substantially entire region of the nitride-based semiconductor laser device 100 in the extensional direction ([1-100] direction) of the cavity. Thus, the nitride-based semiconductor laser device 100 having high luminous efficiency can be easily formed.

The temperature at the formation of the underlayer 20 is rendered higher than the temperature at the formation of the active layer 33, whereby the underlayer 20 on the n-type GaN substrate 10 can be easily lattice-relaxed.

### Second Embodiment

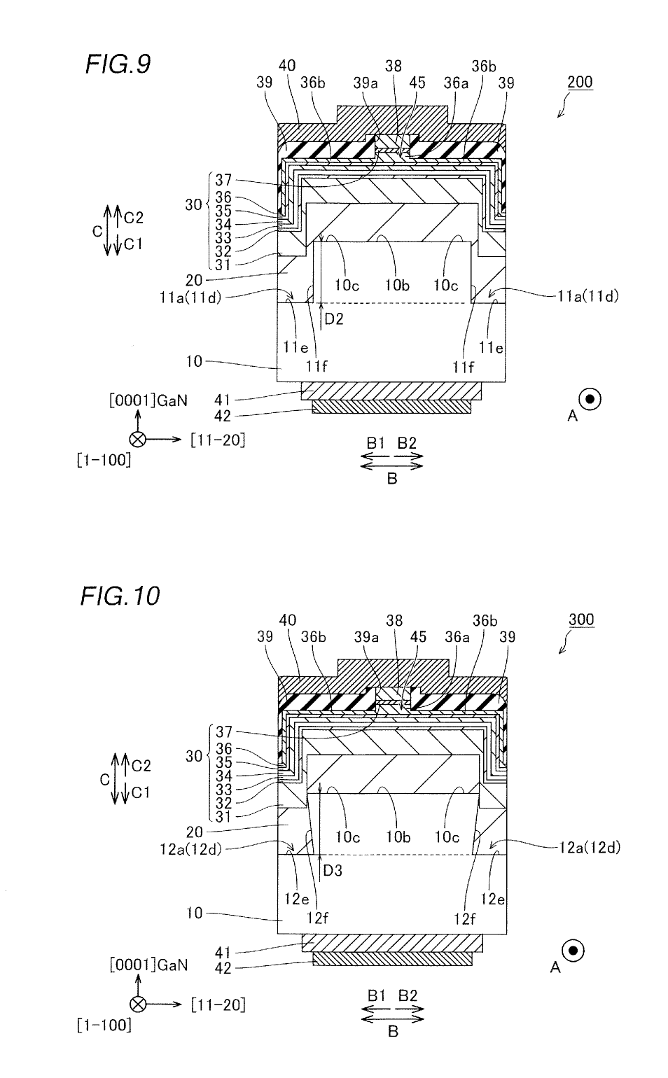

A nitride-based semiconductor laser device 200 according to a second embodiment is now described with reference to FIG. 9. In a manufacturing process of the nitride-based semiconductor laser device 200 according to the second embodiment, an n-type GaN substrate 10 previously formed with groove portions 11d each having a depth of about 5 μm is employed to stack semiconductor device layers, dissimilarly to the first embodiment. In the figure, a structure similar to that of the nitride-based semiconductor laser device 100 according to the first embodiment is denoted by the same reference numerals.

The nitride-based semiconductor laser device 200 has a nitride-based semiconductor layer 30 through an underlayer 20 having a thickness of about 2.5 μm on a surface of the n-type GaN substrate 10, as shown in FIG. 9.

The n-type GaN substrate 10 formed with the underlayer 20 is formed with step portions 11a each having a step (depth) D2 of about 5 μm. Therefore, the underlayer 20 covers an upper surface (surface on a C2 side including the step portions 11a and a terrace portion 10b) of the n-type GaN substrate 10 in a state where a thickness thereof is smaller than the step D2 of each of the step portions 11a. When the underlayer 20 is formed in this manner, a thickness of the underlayer 20 on side surfaces 11f of the step portions 11a is smaller than a thickness of the underlayer 20 on bottom portions 11e of the step portions 11a and a thickness of the underlayer 20 on the terrace portion 10b. Consequently, on the side surfaces 11f of the step portions 11a, the underlayer 20 is easily expanded in an in-plane (in a plane formed by directions A and B) direction of the substrate in the terrace portion 10b.

The remaining structure of the nitride-based semiconductor laser device 200 is similar to that of the first embodiment. The manufacturing process of the nitride-based semiconductor laser device 200 is similar to that of the first embodiment, except that the groove portions 11d (step portions 11a) each having a step D2 of about 5 μm is formed on the upper surface of the n-type GaN substrate 10.

A thickness of the underlayer 20 in the terrace portion 10b of the n-type GaN substrate 10 is smaller than a height of each of the step portions 11a of the n-type GaN substrate 10, whereby the thickness (thickness in a direction (along arrow B) perpendicular to the side surfaces 11f) of the underlayer 20 in the vicinities of corners (portions connecting the side surfaces 11f and ends 10c) of the step portions 11a is smaller than the thicknesses of the underlayer 20 on the bottom portions 11e of the step portions 11a and the terrace portion 10b when growing the underlayer 20 on the surface of the n-type GaN substrate 10, and hence the underlayer 20 is easily expanded in the in-plane direction of the substrate in the terrace portion 10b. Thus, in the terrace portion 10b which is a region other than the step portions 11a, a lattice constant of the underlayer 20 in the in-plane direction of the substrate can be easily rendered larger than a lattice constant of the n-type GaN substrate 10 in the in-plane direction of the substrate when the underlayer 20 is formed on the n-type GaN substrate 10. The remaining effects of the second embodiment are similar to those of the first embodiment.

### Third Embodiment

A nitride-based semiconductor laser device 300 according to a third embodiment is now described with reference to FIG. 10. In a manufacturing process of the nitride-based semiconductor laser device 300 according to the third embodiment, an n-type GaN substrate 10 formed with groove portions 12d each having a side surface 12f inclined in a direction in which an opening width widens inward from an upper surface (surface on a C2 side) of the n-type GaN substrate 10 is employed to stack semiconductor device layers, dissimilarly to the second embodiment. In the figure, a structure similar to that of the nitride-based semiconductor laser device 200 according to the second embodiment is denoted by the same reference numerals.

The nitride-based semiconductor laser device 300 has a nitride-based semiconductor layer 30 through an underlayer 20 having a thickness of about 2.5 μm on a surface of the n-type GaN substrate 10, as shown in FIG. 10.

The n-type GaN substrate 10 formed with the underlayer 20 is formed with step portions 12a having the side surfaces 12f so protruding upward from bottom portions 12e as to form eaves. The step portions 12a each have a height (step) D3 of about 5 μm. Thus, the underlayer 20 is completely divided along arrow B at portions where ends 10c of the n-type GaN substrate 10 and the side surfaces 12f intersect with each other, as viewed along a [11-20] direction (arrow B).

The manufacturing process when forming the groove portions 12d having the side surfaces 12f on the upper surface of the n-type GaN substrate 10 is as follows: When forming the groove portions 12d in the n-type GaN substrate 10, the n-type GaN substrate 10 is obliquely set on a base (not shown) of an etching apparatus and etched in a rotational manner, so that the groove portions 12d each have a cross-sectional shape in a trapezoid with a narrow upper opening width than a base-side width. In other words, the opening width of each of the groove portions 12d is gradually reduced from the bottom portion 12e toward an opening end thereof. Even when the n-type GaN substrate 10 is set parallel to the base of the etching apparatus, the groove portions 12d can each have a cross-sectional shape in a trapezoidal shape by controlling an etching condition such as etching gas pressure.

The remaining structure and manufacturing process of the nitride-based semiconductor laser device 300 are similar to those of the second embodiment.

The underlayer 20 is formed in a state of being completely divided in the [11-20] direction at portions (corners) connecting the ends 10c of the n-type GaN substrate 10 and the side surfaces 12f, whereby the underlayer 20 is formed on the surface of the n-type GaN substrate 10 in a discontinuous state along arrow B, and hence the underlayer 20 is easily expanded in the in-plane direction of the substrate in a terrace portion 10b. Consequently, a lattice constant of underlayer 20 in the in-plane direction of the substrate can be easily rendered larger than a lattice constant of the n-type GaN substrate 10 in the in-plane direction of the substrate in the terrace portion 10b when forming the underlayer 20 on the n-type GaN substrate 10. The remaining effects of the third embodiment are similar to those of the second embodiment.

### Fourth Embodiment

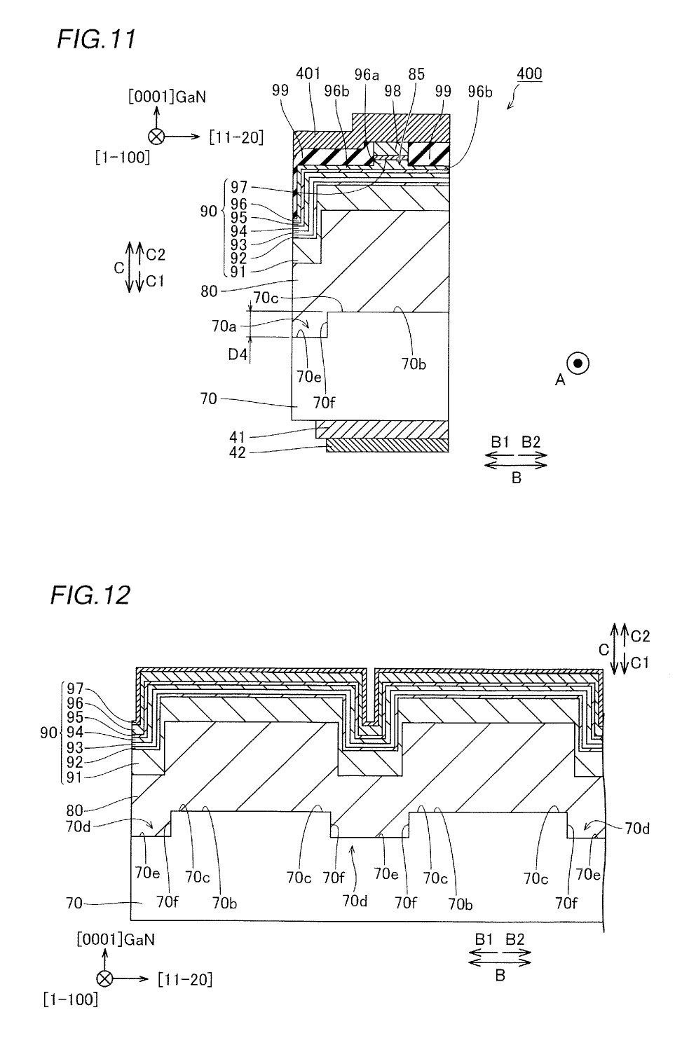

First, a nitride-based semiconductor laser device 400 according to a fourth embodiment is described with reference to FIG. 11. In the figure, a structure similar to that of the nitride-based semiconductor laser device 100 according to the first embodiment is denoted by the same reference numerals.

The nitride-based semiconductor laser device 400 has a nitride-based semiconductor layer 90 through an underlayer 80 made of Ge-doped n-type Al_{0.3}Ga_{0.7}N having a thickness of about 2.5 μm on a surface of an n-type Al_{0.4}Ga_{0.6}N substrate 70 having a main surface of a (0001) plane, as shown in FIG. 11. The nitride-based semiconductor laser device 400 has a cavity length of about 300 μm and a device width of about 125 μm. The n-type Al_{0.4}Ga_{0.6}N substrate 70 is an example of the “substrate” in the present invention.

The n-type Al_{0.4}Ga_{0.6}N substrate 70 is provided with a step portion 70a having a step (depth) D4 of about 2 μm on an end on one side (B1 side) of the device in a width direction ([11-20] direction). Therefore, the underlayer 80 having a thickness of about 2.5 μm covers an upper surface of the n-type Al_{0.4}Ga_{0.6}N substrate 70 in a state of filling up the step portion 70a. A lattice constant of the n-type Al_{0.4}Ga_{0.6}N substrate 70 in the [11-20] direction in an unstrained state is 0.31582 nm.

Thus, an a-axis lattice constant of the underlayer 80 is 0.31659 nm in an unstrained state, whereas a lattice constant of the underlayer 80 in the [11-20] direction is 0.31613 nm in a terrace portion 70b arranged in a central region of the n-type Al_{0.4}Ga_{0.6}N substrate 70 in the [11-20] direction when forming the underlayer 80 on the upper surface of the n-type Al_{0.4}Ga_{0.6}N substrate 70. In other words, the underlayer 80 after formation has a compressive strain of 0.1% in the [11-20] direction in the terrace portion 70b. A lattice constant of the underlayer 80 in the [11-20] direction is 0.31654 nm in a portion above the vicinity of an end 70c of the terrace portion 70b in the [11-20] direction. In other words, the underlayer 80 after formation has a compressive strain of 0.02% in the [11-20] direction in the portion above the vicinity of the end 70c. The terrace portion 70b is an example of the “region other than the step portion” in the present invention.

Therefore, the underlayer 80 after formation on the n-type Al_{0.4}Ga_{0.6}N substrate 70 has a lattice constant larger than the lattice constant (=0.31582 nm) of the n-type Al_{0.4}Ga_{0.6}N substrate 70 in the [11-20] direction in an unstrained state throughout the underlayer 80 in the [11-20] direction. In the vicinity of the step portion 70a, a strain of the underlayer 80 is released on a side surface 70f of the step portion 70a, and hence a compressive strain in the portion above the vicinity of the end 70c is smaller than a compressive strain in a portion above the vicinity of the terrace portion 70b.

Further, a lattice constant of the underlayer 80 in a [1-100] direction after formation on the n-type Al_{0.4}Ga_{0.6}N substrate 70 is equal to the lattice constant (=√3×0.31582 nm) of the n-type Al_{0.4}Ga_{0.6}N substrate 70 in the [1-100] direction in an unstrained state over the entire device regardless of portions above the terrace portion 70b and the step portion 70a, and hence the underlayer 80 has a compressive strain of 0.2% in the [1-100] direction after formation. Thus, a strain of the underlayer 80 in the [1-100] direction after formation on the n-type Al_{0.4}Ga_{0.6}N substrate 70 is larger than a strain thereof in the [11-20] direction.

The nitride-based semiconductor layer 90 on an upper surface (surface on a C2 side) of the underlayer 80 is constituted by an n-type cladding layer 91 made of Ge-doped n-type Al_{0.4}Ga_{0.6}N, having a thickness of about 1.8 μm, an n-side carrier blocking layer 92 made of undoped Al_{0.45}Ga_{0.55}N, having a thickness of about 20 nm and an active layer 93 having an MQW structure in which four barrier layers made of undoped Al_{0.35}Ga_{0.65}N, each having a thickness of about 20 nm and three quantum well layers made of undoped Al_{0.3}Ga_{0.7}N, each having a thickness of about 3.5 nm are alternately stacked from a lower layer toward an upper layer. An a-axis lattice constant of the n-type cladding layer 91 is 0.31582 nm in an unstrained state, similarly to the n-type Al_{0.4}Ga_{0.6}N substrate 70. The n-type cladding layer 91 is an example of the “first semiconductor layer” in the present invention, and the n-side carrier blocking layer 92 and the active layer 93 are an example of the “second semiconductor layer” in the present invention.

A p-side optical guide layer 94 made of undoped Al_{0.35}Ga_{0.65}N, having a thickness of about 0.1 μm, a p-side carrier blocking layer 95 made of undoped Al_{0.45}Ga_{0.55}N, having a thickness of about 20 nm, a p-type cladding layer 96 made of Mg-doped p-type Al_{0.4}Ga_{0.6}N, having a thickness of about 0.45 μm and a p-side contact layer 97 made of undoped GaN, having a thickness of about 3 nm are formed on the active layer 93. The p-side optical guide layer 94, the p-side carrier blocking layer 95, the p-type cladding layer 96 and the p-side contact layer 97 are an example of the “second semiconductor layer” in the present invention.

While an a-axis lattice constant of the well layers of the active layer 93 in an unstrained state is 0.31659 nm, a lattice constant thereof in a portion above the terrace portion 70b is equal to the lattice constant (0.31613 nm) of the underlayer 80 after stacked on the substrate and the well layers of the active layer 33 have a compressive strain of 0.1% in the [11-20] direction when forming the well layers on the underlayer 80. A lattice constant of the well layers in an unstrained state is equal to a lattice constant of the underlayer 80 in an unstrained state. Further, a lattice constant of the well layers in the [11-20] direction in the portion above the vicinity of the end 70c of the terrace portion 70b is equal to the lattice constant (0.31654 nm) of the underlayer 80 after stacked. In other words, the well layers have a compressive strain of 0.02% in the [11-20] direction in a portion above the vicinity of the end 70c.

Therefore, the well layers have a lattice constant larger than the lattice constant (0.31582 nm) of the n-type Al_{0.4}Ga_{0.6}N substrate 70 in the [11-20] direction in an unstrained state throughout the well layers in the [11-20] direction. In the vicinity of the step portion 70a, a strain of the well layers is released on the side surface 70f of the step portion 70a, and hence a compressive strain in a portion above the end 70c is smaller than a compressive strain in the portion above the terrace portion 70b.

A lattice constant of the well layers in a [1-100] direction after formation on the n-side carrier blocking layer 92 is equal to the lattice constant of the n-type Al_{0.4}Ga_{0.6}N substrate 70 in the [1-100] direction in an unstrained state over the entire device regardless of portions above the terrace portion 70b and the step portion 70a, and hence the well layers have a compressive strain of 0.2% in the [1-100] direction after formation as compared with an unstrained state (lattice constant=√3×0.31659 nm). Thus, after formation on the n-side carrier blocking layer 92, a strain of the well layers in the [1-100] direction is larger than a strain of the well layers in the [11-20] direction.

As shown in FIG. 11, the p-type cladding layer 96 is formed with a projecting portion 96a protruding upward (in a direction C2) from a substantially central portion of the device in the width direction, having a thickness (protrusion height) of about 0.402 μm and planar portions 96b extending on both sides of the projecting portion 96a, having a thickness of about 0.05 μm. The projecting portion 96a extends along a cavity direction (direction A in FIG. 11) in a striped manner in a state of having a width of about 1.5 μm in the width direction of the device. The projecting portion 96a of this p-type cladding layer 96 and the p-side contact layer 97 form a ridge 85 for constituting a waveguide in a portion of the active layer 93. A p-side ohmic electrode 98 is formed on the p-side contact layer 97, and a current blocking layer 99 made of SiO₂ is so formed as to cover upper surfaces of the planar portions 96b of the p-type cladding layer 96 and both side surfaces of the ridge 85. A p-side pad electrode 401 is formed on upper surfaces of the p-side ohmic electrode 98 and the current blocking layer 99.

Next, a manufacturing process of the nitride-based semiconductor laser device 400 according to the fourth embodiment is described with reference to FIGS. 11 to 13.

First, the n-type Al_{0.4}Ga_{0.6}N substrate 70 having a main surface of a (0001) plane is prepared, as shown in FIG. 12. Groove portions 70d each having a cross-sectional shape similar to that of the first embodiment are formed.

Next, the layers 91 to 97 made of nitride-based semiconductors constituting the nitride-based semiconductor layer 90 are successively formed on upper surfaces of the terrace portions 70b of the n-type Al_{0.4}Ga_{0.6}N substrate 70 and bottom surfaces and the side surfaces 70f of the groove portions 70d through the underlayer 80 by MOCVD.

More specifically, the underlayer 80 is grown on the surface of the n-type Al_{0.4}Ga_{0.6}N substrate 70 at a growth rate of about 1.1 μm/h when the n-type Al_{0.4}Ga_{0.6}N substrate 70 reaches a temperature of about 1150° C.

At this time, the lattice constant of the underlayer 80 after formation in the [11-20] direction is 0.31613 nm in the terrace portions 70b (the central portions of the devices in the [11-20] direction), and hence the underlayer 80 has a compressive strain of 0.1% in the [11-20] direction. The lattice constant of the underlayer 80 in the [11-20] direction after formation is 0.31654 nm in the ends 70c of the terrace portions 70b, and hence the underlayer 80 has a compressive strain of 0.02% in the [11-20] direction.

On the other hand, the lattice constant of the underlayer 80 in the [1-100] direction after formation is equal to the lattice constant of the n-type Al_{0.4}Ga_{0.6}N substrate 70 in the [1-100] direction in an unstrained state over the entire substrate, and hence the underlayer 80 has a compressive strain of 0.2% in the [1-100] direction as compared with an unstrained state.

Thereafter, in a state where the temperature of the n-type Al_{0.4}Ga_{0.6}N substrate 70 is about 1050° C., the n-type cladding layer 91 is grown on a surface of the underlayer 80 at a growth rate of about 1.1 μm/h. Further, the four barrier layers made of undoped Al_{0.35}Ga_{0.65}N, each having a thickness of about 20 nm and the three quantum well layers made of undoped Al_{0.3}Ga_{0.7}N, each having a thickness of about 3.5 nm are alternately grown on the n-type cladding layer 91 at a growth rate of about 0.25 μm/h. Thus, the active layer 93 is formed.

Then, the p-side optical guide layer 94 is grown on the active layer 93. Thereafter, the p-side carrier blocking layer 95 is grown on the p-side optical guide layer 94 at a growth rate of about 1.2 μm/h. Thereafter, the p-type cladding layer 96 is grown on the p-side carrier blocking layer 95 at a growth rate of about 1.1 μm/h. Thereafter, the p-side contact layer 97 is grown on the p-type cladding layer 96 at a growth rate of about 0.25 μm/h. Thus, the nitride-based semiconductor layer 90 constituted by the nitride-based semiconductor layers (91 to 97) is formed on the upper surfaces of the terrace portions 70b of the n-type Al_{0.4}Ga_{0.6}N substrate 70 and the bottom and side surfaces of the groove portions 70d through the underlayer 80.

At this time, a lattice constant of the nitride-based semiconductor layer 90 in the in-plane direction of the substrate is equal to the lattice constant of the underlayer 80. In other words, the well layers in the active layer 93 has a compressive strain of 0.1% in the [11-20] direction in the portions above the terrace portions 70b and a compressive strain of 0.02% in the [11-20] direction in the portions above the ends 70c of the terrace portions 70b.

The lattice constant of the well layers in the active layer 93 in the [1-100] direction after formation is equal to the lattice constant of the n-type Al_{0.4}Ga_{0.6}N substrate 70 in the [1-100] direction in an unstrained state over the entire substrate, and hence the well layers have a compressive strain of 0.2% in the [1-100] direction.

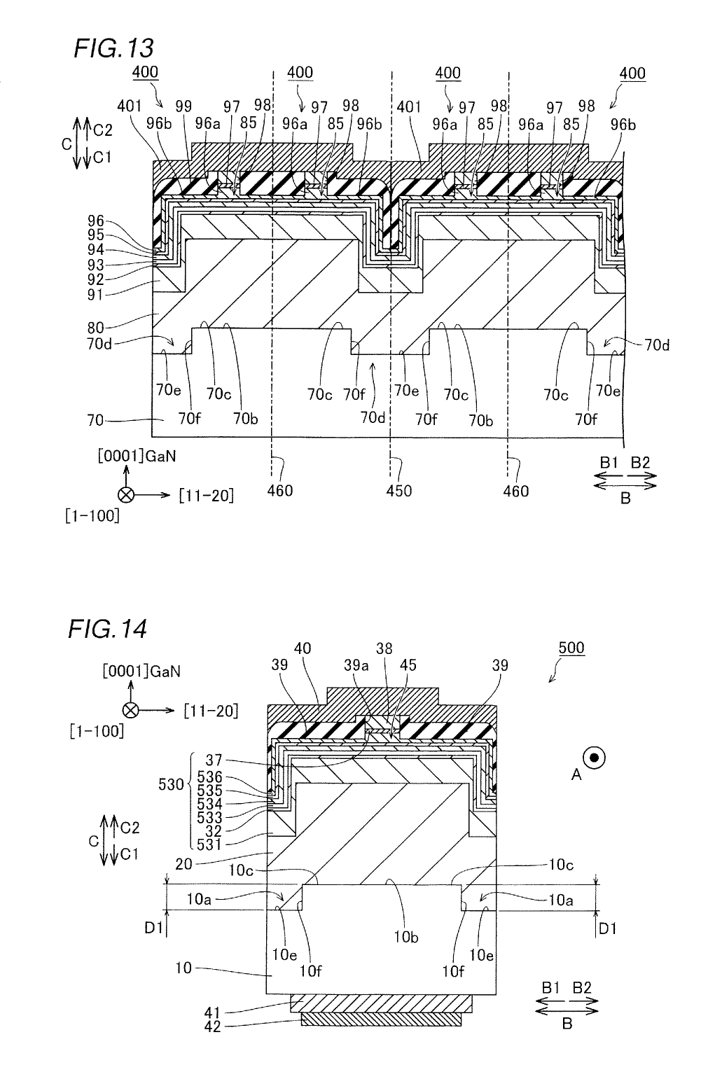

Thereafter, a plurality of the ridge 85 are formed by photolithography and dry etching, as shown in FIG. 13. Thereafter, the p-side ohmic electrode 98, the current blocking layer 99 and the p-side pad electrode 401 are successively formed. After a back surface of the n-type Al_{0.4}Ga_{0.6}N substrate 70 is polished up to a thickness facilitating cleavage in a cleaving step described later, an n-side ohmic electrodes 41 and an n-side pad electrodes 42 are successively formed in a prescribed region on the back surface of the n-type Al_{0.4}Ga_{0.6}N substrate 70.

Finally, a wafer is separated into the devices in the [1-100] direction along the center (isolation line 450 in FIG. 13) of the groove portion 70d of the n-type Al_{0.4}Ga_{0.6}N substrate 70 and along central portions (isolation lines 460 in FIG. 13) of regions between the two ridges 85. Thus, the step portion 70a after separating the groove portion 70d into two is left on an end on one side of the each chip in a width direction. Thus, the nitride-based semiconductor laser device 400 according to the fourth embodiment shown in FIG. 11 is formed.

The step portion 70a is formed on an end on one side of the n-type Al_{0.4}Ga_{0.6}N substrate 70 in the [11-20] direction (along arrow B). Thus, the single nitride-based semiconductor laser device 400 is formed with the step portion 70a on one side, and hence the central region (terrace portion 70b) of the n-type Al_{0.4}Ga_{0.6}N substrate 70 can be sufficiently secured. Consequently, a width of the nitride-based semiconductor laser device 400 along arrow B can be reduced.

The temperature at the time of forming the n-type cladding layer 91 is set to be not higher than the temperature at the formation of the underlayer 80, whereby the n-type cladding layer 91 can be formed on the surface of the underlayer 80 in a state of maintaining the lattice relaxation of the underlayer 80. The effects of the fourth embodiment are similar to those of the first embodiment.

### Fifth Embodiment

A nitride-based semiconductor laser device 500 according to a fifth embodiment is described with reference to FIG. 14. In the nitride-based semiconductor laser device 500, an n-type cladding layer 531 made of a material different from that employed in the first embodiment is employed to form a nitride-based semiconductor layer 530. In the figure, a structure similar to that of the nitride-based semiconductor laser device 100 according to the first embodiment is denoted by the same reference numerals.

In other words, in a manufacturing process of the nitride-based semiconductor laser device 500, an underlayer 20 is grown on a surface of an n-type GaN substrate 10, and thereafter in a state where the temperature of the n-type GaN substrate 10 is about 800° C., an n-type cladding layer 531 made of Si-doped n-type In_{0.15}Ga_{0.85}N having a thickness of about 1.5 μm is grown on a surface of the underlayer 20 at a growth rate of about 0.25 μm/h. The n-type cladding layer 531 has a lattice constant (in an a-axis direction ([11-20] direction)) of 0.32406 nm in an unstrained state.

Next, an n-side carrier blocking layer 32 is formed on a surface of the n-type cladding layer 531, and thereafter four barrier layers of undoped In_{0.2}Ga_{0.8}N each having a thickness of about 20 nm and three quantum well layers of undoped In_{0.35}Ga_{0.65}N each having a thickness of about 3.5 nm are alternately grown at a growth rate of about 0.25 μm/h. Thus, an active layer 533 having an MQW structure obtained by alternately stacking the four barrier layers and the three quantum well layers is formed. The n-type cladding layer 531 is an example of the “first semiconductor layer” in the present invention, and the active layer 533 is an example of the “second semiconductor layer” in the present invention.

While the well layers of the active layer 533 has an a-axis lattice constant of 0.33094 nm in an unstrained state, the well layers have a compressive strain of 3.2% in the [11-20] direction so as to become equal to a lattice constant (0.32028 nm) of the underlayer 20 in a portion above a terrace portion 10b when formed on the underlayer 20. A lattice constant of the well layers in the [11-20] direction in portions above ends 10c of the terrace portion 10b is equal to a lattice constant (0.32213 nm) of the underlayer 20 after stacked. In other words, the well layers have a compressive strain of 2.7% in the [11-20] direction in the portions above the ends 10c.

Therefore, the well layers have a lattice constant larger than a lattice constant (=0.3189 nm) of the n-type GaN substrate 10 in the [11-20] direction in an unstrained state throughout the well layers in the [11-20] direction.

A lattice constant of the well layers in a [1-100] direction after formation on the n-side carrier blocking layer 32 is equal to a lattice constant (√3×0.3189 nm) of the n-type GaN substrate 10 in the [1-100] direction in an unstrained state over the entire device regardless of portions above the terrace portion 10b and step portions 10a, and hence the well layers have a compressive strain of about 3.6% in the [1-100] direction after formation as compared with an unstrained state (lattice constant=√3×0.33094 nm). Thus, a strain of the well layers in the [1-100] direction after formation on the n-side carrier blocking layer 32 is larger than a strain of the well layers in the [11-20] direction.

Then, a p-side optical guide layer 534 made of undoped In_{0.2}Ga_{0.8}N, having a thickness of about 0.1 μm is grown on the active layer 533. Thereafter, a p-side carrier blocking layer 535 made of undoped Al_{0.1}Ga_{0.9}N, having a thickness of about 20 nm is grown on the p-side optical guide layer 534 at a growth rate of about 1.2 μm/h. Thereafter, a p-type cladding layer 536 made of Mg-doped p-type Al_{0.03}Ga_{0.97}N, having a thickness of about 0.45 μm is grown on the p-side carrier blocking layer 535 at a growth rate of about 1.1 μm/h. Thereafter, a p-side contact layer 37 made of undoped In_{0.07}Ga_{0.93}N, having a thickness of about 3 nm is grown on the p-type cladding layer 536 at a growth rate of about 0.25 μm/h. The p-side optical guide layer 534, the p-side carrier blocking layer 535 and the p-type cladding layer 536 are an example of the “second semiconductor layer” in the present invention.

The remaining structure and manufacturing process of the nitride-based semiconductor laser device 500 are similar to those of the first embodiment. The effects of the fifth embodiment are similar to those of the first embodiment.

### Sixth Embodiment

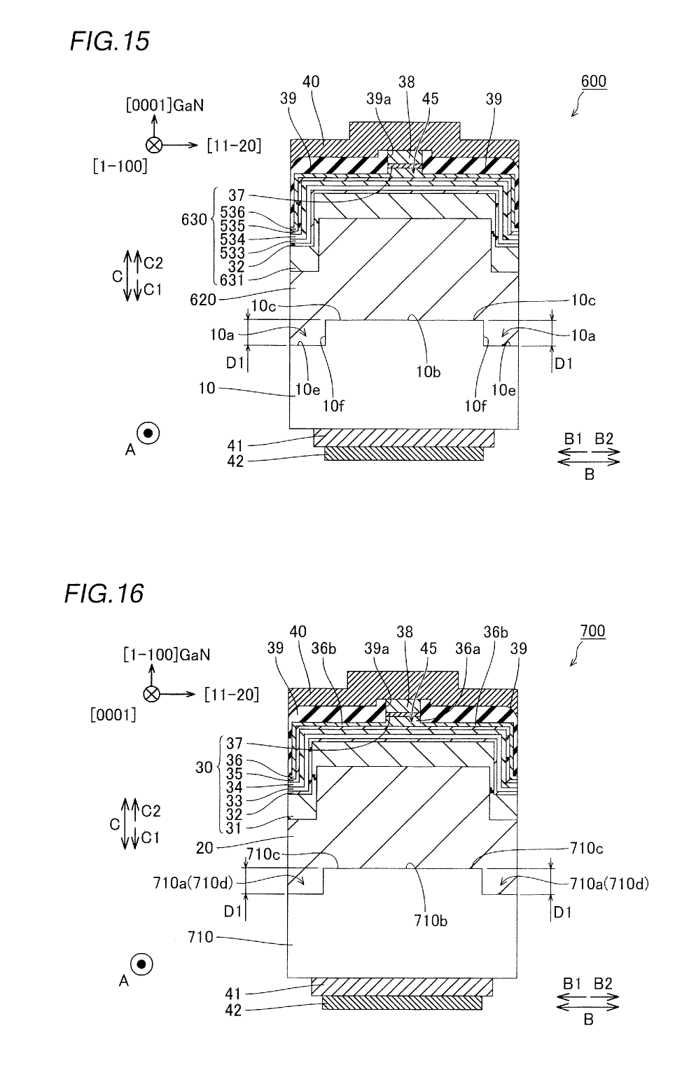

A nitride-based semiconductor laser device 600 according to a sixth embodiment is described with reference to FIG. 15. In the nitride-based semiconductor laser device 600, an underlayer 620 and an n-type cladding layer 631 each made of a material different from that employed in the fifth embodiment are employed to form a nitride-based semiconductor layer 630 on a surface of an n-type GaN substrate 10. In the figure, a structure similar to that of the nitride-based semiconductor laser device 500 according to the fifth embodiment is denoted by the same reference numerals.

In other words, in a manufacturing process of the nitride-based semiconductor laser device 600, an underlayer 620 made of n-type Al_{0.05}In_{0.1}Ga_{0.85}N, having a thickness of about 2.5 μm is grown on the surface of the n-type GaN substrate 10. An a-axis lattice constant of the underlayer 620 is 0.32196 nm in an unstrained state.

At this time, a lattice constant of the underlayer 620 in a [11-20] direction after formation is 0.32012 nm in a terrace portion 10b (central portion of the device in the [11-20] direction), and hence the underlayer 620 has a compressive strain of 0.6% in the [11-20] direction. A lattice constant of the underlayer 620 in the [11-20] direction after formation is 0.32177 nm in ends 10c of the terrace portion 10b, and hence the underlayer 620 has a compressive strain of 0.1% in the [11-20] direction.

On the other hand, a lattice constant of the underlayer 620 in a [1-100] direction after formation on the n-type GaN substrate is equal to a lattice constant of the n-type GaN substrate 10 in the [1-100] direction in an unstrained state over the entire substrate, and hence the underlayer 620 has a compressive strain of 0.9% in the [1-100] direction after formation. In other words, a strain of the underlayer 620 in the [1-100] direction after formation on the n-type GaN substrate 10 is larger than a strain thereof in the [11-20] direction.

Thereafter, an n-type cladding layer 631 made of Ge-doped n-type Al_{0.05}Ga_{0.95}N, having a thickness of about 1.8 μm is grown on a surface of the underlayer 620 at a growth rate of about 0.25 μm/h. The remaining semiconductor layers (semiconductor device layers) stacked on a surface of the n-type cladding layer 631 are similar to those of the fifth embodiment. The n-type cladding layer 631 is an example of the “first semiconductor layer” in the present invention.

Thus, while well layers of an active layer 533 has an a-axis lattice constant of 0.33094 nm in an unstrained state, the well layers have a compressive strain of 3.3% in the [11-20] direction so as to become equal to a lattice constant (0.32012 nm) of the underlayer 620 after formation in a portion above the terrace portion 10b when formed on the underlayer 620. A lattice constant of the well layers in the [11-20] direction is equal to the lattice constant (0.32177 nm) of the underlayer 620 in portions above the ends 10c of the terrace portion 10b. In other words, the well layers have a compressive strain of 2.8% in the [11-20] direction in the portions above the ends 10c.

Therefore, the well layers have a lattice constant larger than a lattice constant of the n-type GaN substrate 10 in the [11-20] direction throughout the well layers in the [11-20] direction.

A lattice constant of the well layers in the [1-100] direction after formation on an n-side carrier blocking layer 32 is equal to a lattice constant of the n-type GaN substrate 10 in the [1-100] direction in an unstrained state over the entire device regardless of portions above the terrace portion 10b and step portions 10a, and hence the well layers have a compressive strain of about 0.6% in the [1-100] direction after formation as compared with an unstrained state (lattice constant=√3×0.33094 nm). Thus, a strain of the well layers in the [1-100] direction after formation on the n-side carrier blocking layer 32 is larger than a strain thereof in the [11-20] direction.

The remaining structure and manufacturing process of the nitride-based semiconductor laser device 600 are similar to those of the fifth embodiment. The effects of the sixth embodiment are similar to those of the first embodiment.

### Seventh Embodiment

A nitride-based semiconductor laser device 700 according to a seventh embodiment is described with reference to FIG. 16. In the nitride-based semiconductor laser device 700, an n-type GaN substrate 710 having a main surface of a (1-100) plane is employed to form a nitride-based semiconductor layer 30, dissimilarly to the first embodiment. In the figure, a structure similar to that of the nitride-based semiconductor laser device 100 according to the first embodiment is denoted by the same reference numerals.

In other words, in a manufacturing process of the nitride-based semiconductor laser device 700, groove portions 710d in a striped (slender) shape extending along a [0001] direction (direction A) are formed on a surface of the n-type GaN substrate 710 having a main surface of a (1-100) plane. A c-axis lattice constant of the n-type GaN substrate 710 is 0.5186 nm in an unstrained state. The groove portions 710d each have the same cross-sectional shape as that of each of the groove portions 10d formed in the first embodiment. The n-type GaN substrate 710 is an example of the “substrate” in the present invention.

Thereafter, an underlayer 20 is grown on the surface of the n-type GaN substrate 710 formed with the groove portions 710d. A c-axis lattice constant of the underlayer 20 is 0.52367 nm in an unstrained state. A value calculated by linear interpolation setting a c-axis lattice constant of InN to 0.5693 nm is employed for the lattice constant of the underlayer 20 in an unstrained state.

At this time, according to the seventh embodiment, a lattice constant of the underlayer 20 in a [11-20] direction is 0.32028 nm in a terrace portion 710b (central portion of the device in the [11-20] direction), and hence the underlayer 20 has a compressive strain of 0.6% in the [11-20] direction. A lattice constant of the underlayer 20 in the [11-20] direction is 0.32213 nm in ends 710c of the terrace portion 710b, and hence the underlayer 20 has a compressive strain of 0.1% in the [11-20] direction. The terrace portion 710b is an example of the “region other than the step portion” in the present invention.

On the other hand, a lattice constant of the underlayer 20 in the [0001] direction after formation on the n-type GaN substrate 710 is equal to a lattice constant of the n-type GaN substrate 710 in the [0001] direction in an unstrained state over the entire substrate, and hence the underlayer 20 has a compressive strain of 1% in the [0001] direction after formation. In other words, a strain of the underlayer 20 in the [0001] direction after formation on the n-type GaN substrate 710 is larger than a strain thereof in the [11-20] direction.

Thereafter, semiconductor layers (semiconductor device layers) made of materials similar to those of the first embodiment are stacked on a surface of the underlayer 20 to form a nitride-based semiconductor layer 30.

Thus, well layers of an active layer 33 after formation have a compressive strain of 2.7% in the [11-20] direction in a portion above the terrace portion 710b and a compressive strain of 2.2% in the [11-20] direction in portions above the ends 710c of the terrace portion 710b, similarly to the first embodiment.

A lattice constant of the well layers in a [1-100] direction after formation on an n-side carrier blocking layer 32 is equal to the lattice constant of the n-type GaN substrate 710 in the [0001] direction in an unstrained state over the entire device regardless of portions above the terrace portion 710b and step portions 710a, and hence the well layers have a compressive strain of 2.8% in the direction after formation as compared with an unstrained state (lattice constant=0.53381 nm). Thus, a strain of the well layers in the [0001] direction after formation on the n-side carrier blocking layer 32 is larger than a strain thereof in the [11-20] direction.

The remaining structure and manufacturing process of the nitride-based semiconductor laser device 700 are similar to those of the first embodiment.

The underlayer 20 is formed on the main surface of an m-plane ((1-100) plane) of the n-type GaN substrate 710 in a state where a strain thereof in the [0001] direction is larger than a strain thereof in the [11-20] direction, whereby an anisotropic strain can be applied in the in-plane direction of the substrate of a hexagonal compound semiconductor constituting the active layer 33 made of a nitride-based semiconductor. Thus, the nitride-based semiconductor laser device 700 having a reduced threshold current can be formed. The effects of the seventh embodiment are similar to those of the first embodiment.

### Eighth Embodiment

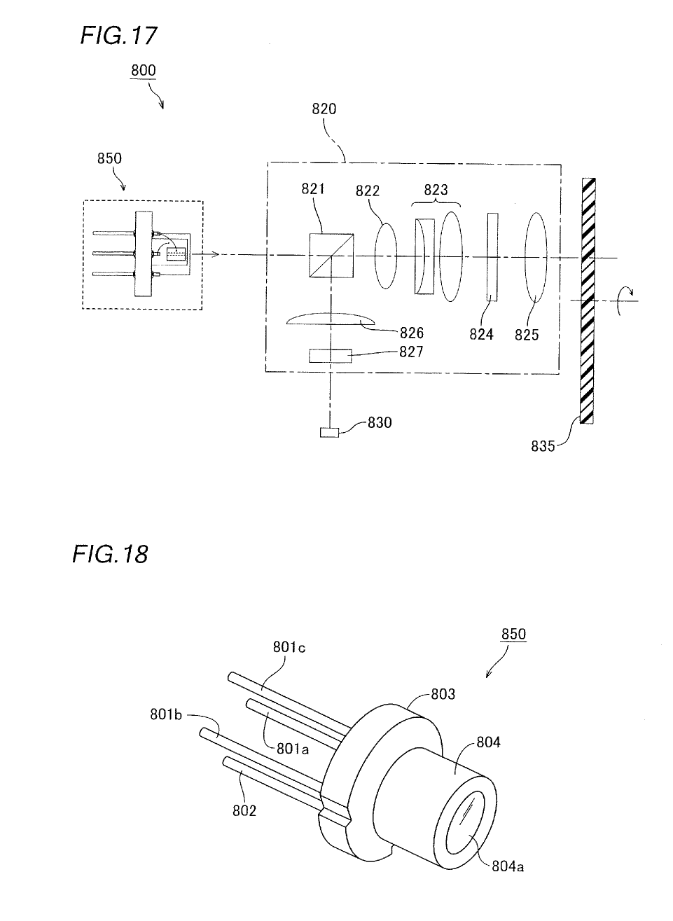

An optical pickup 800 according to an eighth embodiment of the present invention is now described with reference to FIGS. 17 to 19. The optical pickup 800 is an example of the “optical apparatus” in the present invention.

As shown in FIG. 17, the optical pickup 800 comprises a semiconductor laser apparatus 850 emitting a laser beam of a wavelength of blue-violet, an optical system 820 adjusting the laser beam emitted from the semiconductor laser apparatus 850 and a light detection portion 830 receiving the laser beam. The nitride-based semiconductor laser device 100 according to the first embodiment is mounted in the semiconductor laser apparatus 850.

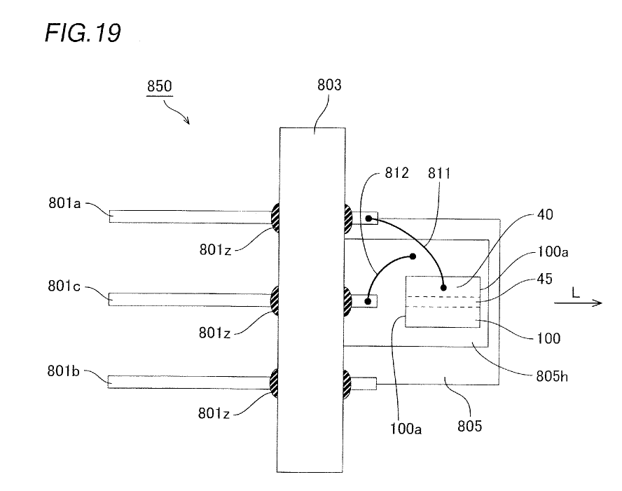

The semiconductor laser apparatus 850 comprises a can package body 803 of a conductive material having a substantially circular shape, power feeding pins 801a, 801b, 801c and 802 and a lid body 804. The nitride-based semiconductor laser device 100 according to the first embodiment is provided on the can package body 803, and sealed with the lid body 804. The lid body 804 is provided with an extraction window 804a of a material transmitting the laser beam. The power feeding pin 802 is mechanically and electrically connected with the can package body 803. The power feeding pin 802 is employed as an earth terminal. Ends of the power feeding pins 801a, 801b, 801c and 802 extending outward from the can package body 803 are connected to respective driving circuits (not shown), as shown in FIGS. 18 and 19.

A conductive submount 805h is provided on a conductive support member 805 integrated with the can package body 803. The support member 805 and the submount 805h are made of a material excellent in conductivity and thermal conductivity. The nitride-based semiconductor laser device 100 is so bonded that a laser beam emitting direction L is directed to the outer side of the semiconductor laser apparatus 850 (toward the extraction window 804a) and a light-emitting point (the waveguide formed under the ridge 45) of the nitride-based semiconductor laser device 100 is positioned on a centerline of the semiconductor laser apparatus 850.

The power feeding pins 801a, 801b and 801c are electrically insulated from the can package body 803 by insulating rings 801z. The power feeding pin 801a is connected to an upper surface of the p-side pad electrode 40 of the nitride-based semiconductor laser device 100 through a wire 811. The power feeding pin 801c is connected to an upper surface of the submount 805h through a wire 812.

As shown in FIG. 17, the optical system 820 has a polarizing beam splitter (PBS) 821, a collimator lens 822, a beam expander 823, a λ/4 plate 824, an objective lens 825, a cylindrical lens 826 and an optical axis correction device 827.

The PBS 821 totally transmits the laser beam emitted from the semiconductor laser apparatus 850, and totally reflects a laser beam fed back from an optical disc 835. The collimator lens 822 converts the laser beam emitted from the semiconductor laser apparatus 850 and transmitted through the PBS 821 to a parallel beam. The beam expander 823 is constituted by a concave lens, a convex lens and an actuator (not shown). The actuator has a function of correcting a wavefront state of the laser beam emitted from the semiconductor laser apparatus 850 by varying a distance between the concave lens and the convex lens in response to servo signals from a servo circuit described later.

The λ/4 plate 824 converts the linearly polarized laser beam, substantially converted to the parallel beam by the collimator lens 822, to a circularly polarized beam. Further, the λ/4 plate 824 converts the circularly polarized laser beam fed back from the optical disc 835 to a linearly polarized beam. In this case, a direction of polarization of the linearly polarized beam is orthogonal to a direction of polarization of the linearly polarized laser beam emitted from the semiconductor laser apparatus 850. Thus, the PBS 821 substantially totally reflects the laser beam fed back from the optical disc 835. The objective lens 825 converges the laser beam transmitted through the λ/4 plate 824 on a surface (recording layer) of the optical disc 835. The objective lens 825 is movable in a focus direction, a tracking direction and a tilt direction by an objective lens actuator (not shown) in response to the servo signals (a tracking servo signal, a focus servo signal and a tilt servo signal) from the servo circuit described later.

The cylindrical lens 826, the optical axis correction device 827 and the light detection portion 830 are arranged to be along an optical axis of the laser beam totally reflected by the PBS 821. The cylindrical lens 826 provides the incident laser beam with astigmatic action. The optical axis correction device 827 is formed by diffraction grating and so arranged that a spot of zeroth-order diffracted light of each of blue-violet, red and infrared laser beams transmitted through the cylindrical lens 826 coincides with each other on a detection region of the light detection portion 830 described later.

The light detection portion 830 outputs a playback signal on the basis of an intensity distribution of the received laser beam. The light detection portion 830 has a detection region of a prescribed pattern, to obtain a focus error signal, a tracking error signal and a tilt error signal along with the playback signal. The optical pickup 800 comprising the semiconductor laser apparatus 850 is constituted in the aforementioned manner.

As hereinabove described, the laser beam emitted from the semiconductor laser apparatus 850 is adjusted by the PBS 821, the collimator lens 822, the beam expander 823, the λ/4 plate 824, the objective lens 825, the cylindrical lens 826 and the optical axis correction device 827, and thereafter irradiated on the detection region of the light detection portion 830.

While controlling laser power emitted from the nitride-based semiconductor laser device 100 to be constant, the laser beam is irradiated on the recording layer of the optical disc 835 and the playback signal output from the light detection portion 830 can be obtained when data recorded in the optical disc 835 is playbacked. The actuator of the beam expander 423 and the objective lens actuator driving the objective lens 425 can be feedback-controlled by the focus error signal, the tracking error signal and the tilt error signal simultaneously output. The actuator of the beam expander 823 and the objective lens actuator driving the objective lens 825 can be feedback-controlled by the focus error signal, the tracking error signal and the tilt error signal simultaneously output.

When data is recorded in the optical disc 835, the laser beam is applied to the optical disc 835 while controlling the laser power emitted from the nitride-based semiconductor laser device 100 according to data to be recorded. Thus, the data can be recorded in the recording layer of the optical disc 835. Similarly to the above, the actuator of the beam expander 823 and the objective lens actuator driving the objective lens 825 can be feedback-controlled by the focus error signal, the tracking error signal and the tilt error signal output from the light detection portion 830.

Thus, record in the optical disc 835 and playback can be performed with the optical pickup 800 comprising the semiconductor laser apparatus 850.

The semiconductor laser apparatus 850 mounted in the optical pickup 800 comprises the aforementioned nitride-based semiconductor laser device 100, and hence the semiconductor laser apparatus 850 having high reliability, capable of enduring the use for a long time by elongating the lifetime of the semiconductor laser device can be obtained.

Although the present invention has been described and illustrated in detail, it is clearly understood that the same is by way of illustration and example only and is not to be taken by way of limitation, the spirit and scope of the present invention being limited only by the terms of the appended claims.

For example, while the n-type nitride-based semiconductor substrate is employed in each of the aforementioned first to eighth embodiments, the present invention is not restricted to this. According to the present invention, a p-type nitride-based semiconductor substrate may be employed and a semiconductor device may be formed by successively stacking a p-type nitride-based semiconductor layer, an active layer, an n-type nitride-based semiconductor layer, etc. on a surface of the p-type nitride-based semiconductor substrate.

While the side surfaces 12f on both sides of the groove portion 12d so protrude upward from the bottom portion 12e as to form the eaves in the manufacturing process of the aforementioned third embodiment, the present invention is not restricted to this. According to the present invention, only the side surface on one side of the groove portion 12d may so protrude upward as to form the eave.

While nitride-based semiconductor layers are crystal-grown by MOCVD in the manufacturing process of each of the aforementioned first to eighth embodiments, the present invention is not restricted to this. According to the present invention, the nitride-based semiconductor layers may be crystal-grown by halide vapor phase epitaxy, molecular beam epitaxy (MBE), gas-source MBE or the like.

A substrate having a dislocation concentrated region in a striped shape may be employed as the “substrate” in the present invention in each of the aforementioned first to eighth embodiments. In this case, the dislocation concentrated region of the substrate is preferably located at a region in a bottom portion of the “step portion” in the present invention, and a region other than the dislocation concentrated region of the substrate is preferably located at the “region other than the step portion” in the present invention.

While the optical pickup 800 loaded with the “semiconductor device” in the present invention is shown in the aforementioned eighth embodiment, the present invention is not restricted to this, but the “semiconductor device” in the present invention may be applied to an optical disc apparatus performing record in an optical disc such as CD, DVD or BD and playback of the optical disc and an optical apparatus such as a projector.

What is claimed is:

1. A semiconductor device comprising:
a substrate made of a nitride-based semiconductor having a main surface parallel to a first direction and a second direction intersecting with said first direction;
an underlayer made of a nitride-based semiconductor formed on said main surface;
a first semiconductor layer made of a nitride-based semiconductor formed on an opposite surface of said underlayer to said substrate; and
a second semiconductor layer made of a nitride-based semiconductor formed on an opposite surface of said first semiconductor layer to said underlayer, wherein
a step portion extending along said first direction is formed on said main surface,
unstrained lattice constants of said underlayer and said second semiconductor layer in said second direction are larger than a lattice constant of said substrate in said second direction in an unstrained state, and
lattice constants of said underlayer and said second semiconductor layer in said second direction in a state of being formed on said main surface of said substrate are larger than said lattice constant of said substrate in said second direction.

2. The semiconductor device according to claim 1, wherein
said lattice constant of said underlayer in said second direction in a region other than at least said step portion of said main surface is larger than said lattice constant of said substrate in said second direction, and
said lattice constant of said second semiconductor layer in said second direction in a region other than at least said step portion of said main surface is larger than said lattice constant of said substrate in said second direction.

3. The semiconductor device according to claim 1, wherein
said underlayer is formed on said substrate in a state where a strain of said underlayer in said first direction is larger than a strain of said underlayer in said second direction.

4. The semiconductor device according to claim 1, wherein
a lattice constant of said underlayer in said first direction in a state where said underlayer is formed on said main surface of said substrate is substantially equal to a lattice constant of said substrate in said first direction.

5. The semiconductor device according to claim 1, wherein
a lattice constant of said second semiconductor layer in said first direction in a state where said second semiconductor layer is formed on said surface of said first semiconductor layer is substantially equal to a lattice constant of said underlayer in said first direction in a state where said underlayer is formed on said main surface.

6. The semiconductor device according to claim 1, wherein
said lattice constant of said second semiconductor layer in said second direction in a state where said second semiconductor layer is formed on said surface of said first semiconductor layer is substantially equal to said lattice constant of said underlayer in said second direction in a state where said underlayer is formed on said main surface.

7. The semiconductor device according to claim 1, wherein
a thickness of said underlayer is larger than a thickness of said first semiconductor layer.

8. The semiconductor device according to claim 1, wherein
an unstrained lattice constant of said first semiconductor layer in said first direction is smaller than an unstrained lattice constant of said underlayer in said first direction, and
an unstrained lattice constant of said first semiconductor layer in said second direction is smaller than said unstrained lattice constant of said underlayer in said second direction.

9. The semiconductor device according to claim 1, wherein
said substrate does not contain In, and said underlayer and said second semiconductor layer contain In.

10. The semiconductor device according to claim 9, wherein
a content of In in said second semiconductor layer is larger than a content of In in said underlayer.

11. The semiconductor device according to claim 9, wherein
said underlayer is made of InGaN.

12. The semiconductor device according to claim 9, wherein
said second semiconductor layer is made of InGaN.

13. The semiconductor device according to claim 1, wherein
a thickness of said underlayer in a region other than said step portion is smaller than a height of said step portion.

14. The semiconductor device according to claim 1, wherein
said step portion has a side surface extending along said first direction, and
said side surface is inclined by an acute angle to said main surface of said substrate in a region other than said step portion.

15. The semiconductor device according to claim 1, wherein
said second semiconductor layer includes an active layer having a well layer, and
an unstrained lattice constant of said well layer in said second direction is larger than said lattice constant of said substrate in said second direction in an unstrained state.

16. The semiconductor device according to claim 15, wherein
said second semiconductor layer is a semiconductor laser device layer including said active layer, and
said second semiconductor layer has a waveguide extending along said first direction.

17. The semiconductor device according to claim 13, wherein
said step portion has a portion without said underlayer or a portion where a thickness of said underlayer in said step portion is smaller than a thickness of said underlayer in a region other than said step portion.

18. A method of manufacturing a semiconductor device comprising steps of:
forming a step portion extending along a first direction on a main surface of a substrate made of a nitride-based semiconductor having said main surface parallel to said first direction and a second direction intersecting with said first direction;
forming an underlayer made of a nitride-based semiconductor on said main surface of said substrate;
forming a first semiconductor layer made of a nitride-based semiconductor on a surface of said underlayer on an opposite side to said substrate; and
forming a second semiconductor layer made of a nitride-based semiconductor on a surface of said first semiconductor layer on an opposite side to said underlayer, wherein
unstrained lattice constants of said underlayer and said second semiconductor layer in said second direction are larger than a lattice constant of said substrate in said second direction in an unstrained state, and
said step of forming said underlayer and said step of forming said second semiconductor layer include a step of forming said underlayer and said second semiconductor layer so that lattice constants of said underlayer and said second semiconductor layer in said second direction are larger than said lattice constant of said substrate in said second direction.

19. The method of manufacturing a semiconductor device according to claim 18, wherein
said step of forming said underlayer includes a step of growing said underlayer at a first temperature,
said step of forming said first semiconductor layer includes a step of growing said first semiconductor layer at a second temperature,
said step of forming said second semiconductor layer includes a step of growing said second semiconductor layer at a third temperature, and
said first temperature is higher than said third temperature.

20. An optical apparatus comprising:
a semiconductor device; and
an optical system adjusting emission light from said semiconductor device,
said semiconductor device includes:
a substrate made of a nitride-based semiconductor having a main surface parallel to a first direction and a second direction intersecting with said first direction;
an underlayer made of a nitride-based semiconductor formed on said main surface;
a first semiconductor layer made of a nitride-based semiconductor formed on an opposite surface of said underlayer to said substrate; and
a second semiconductor layer made of a nitride-based semiconductor formed on an opposite surface of said first semiconductor layer to said underlayer, wherein
a step portion extending along said first direction is formed on said main surface of said substrate,
unstrained lattice constants of said underlayer and said second semiconductor layer in said second direction are larger than a lattice constant of said substrate in said second direction in an unstrained state, and
lattice constants of said underlayer and said second semiconductor layer in said second direction in a state of being formed on said main surface of said substrate are larger than said lattice constant of said substrate in said second direction.
